(19) United States
(12) Patent Application Publication
(10) Pub. No.: US 2026/0182070 A1
(43) Pub. Date: Jun. 25, 2026

(54) SOLID-STATE IMAGING DEVICE, MANUFACTURING METHOD, AND ELECTRONIC EQUIPMENT

(71) Applicant: SONY SEMICONDUCTOR SOLUTIONS CORPORATION, KANAGAWA (JP)

(72) Inventor: YOSHIAKI KIKUCHI, KANAGAWA (JP)

(21) Appl. No.: 19/127,427

(22) PCT Filed: Oct. 30, 2023
(86) PCT No.: PCT/JP2023/039087

§ 371 Date: May 6, 2025

(30) Foreign Application Priority Data
Nov. 15, 2022 (JP) 2022-182220

(51) Int. Cl. H10F 39/00; H10F 39/12

(52) U.S. Cl. CPC H10F 39/811; H10F 39/199; H10F 39/8033; H10F 39/804; H10F 39/8057; H10F 39/806

(57) ABSTRACT

The present disclosure relates to a solid-state imaging device, a manufacturing method, and electronic equipment capable of further raising performance. The solid-state imaging device includes a first transistor that includes a sidewall surrounding a side surface of the first transistor, and a second transistor that is connected in series with the first transistor and includes a sidewall surrounding a side surface of the second transistor. In addition, a first high-concentration diffusion layer provided on a semiconductor substrate and reaching a lower side of the sidewall on a drain side of the first transistor has a lower impurity concentration than a third high-concentration diffusion layer provided on the semiconductor substrate between the first transistor and the second transistor and reaching a lower side of the sidewall on a source side of the first transistor. For example, the present technology is applicable to a more miniaturized solid-state imaging device.

### TECHNICAL FIELD

The present disclosure relates to a solid-state imaging device, a manufacturing method, and electronic equipment, and particularly to a solid-state imaging device, a manufacturing method, and electronic equipment capable of further raising performance.

### BACKGROUND ART

Various technologies for improving performance of transistors included in semiconductor devices, such as solid-state imaging devices, have hitherto been developed.

For example, PTL 1 discloses a semiconductor device which includes MOS-type transistors each having a source containing an impurity of a type different from that of a drain of the transistor and having a higher impurity diffusion coefficient than the drain to have further increased reliability.

### CITATION LIST

### Patent Literature

### [PTL 1]

Japanese Patent Laid-open No. Hei5-343672

### SUMMARY

### Technical Problems

Meanwhile, a manufacturing method disclosed in PTL 1 is difficult to apply to miniaturization of solid-state imaging devices promoted in recent years. Moreover, a sidewall width tends to decrease in association with this miniaturization of solid-state imaging devices. Accordingly, there is a concern that performance of transistors may be lowered by aging deterioration caused by hot carriers, degradation of source follower characteristics, or for other reasons.

The present disclosure developed in consideration of the abovementioned circumstances further raises performance.

### Solution to Problems

A solid-state imaging device according to one aspect of the present disclosure includes a first transistor that includes a sidewall surrounding a side surface of the first transistor, a second transistor that is connected in series with the first transistor and includes a sidewall surrounding a side surface of the second transistor, a first high-concentration diffusion layer that is provided on a semiconductor substrate and reaches a lower side of the sidewall on a drain side of the first transistor, and a third high-concentration diffusion layer that is provided on the semiconductor substrate between the first transistor and the second transistor and reaches a lower side of the sidewall on a source side of the first transistor. The first high-concentration diffusion layer has a lower impurity concentration than the third high-concentration diffusion layer.

A manufacturing method according to one aspect of the present disclosure is a manufacturing method of a solid-state imaging device including a first transistor that includes a sidewall surrounding a side surface of the first transistor, and a second transistor that is connected in series with the first transistor and includes a sidewall surrounding a side surface of the second transistor, the manufacturing method including forming a first high-concentration diffusion layer that is provided on a semiconductor substrate and reaches a lower side of the sidewall on a drain side of the first transistor, and forming a third high-concentration diffusion layer that is provided on the semiconductor substrate between the first transistor and the second transistor and reaches a lower side of the sidewall on a source side of the first transistor. The first high-concentration diffusion layer has a lower impurity concentration than the third high-concentration diffusion layer.

Electronic equipment according to one aspect of the present disclosure includes a solid-state imaging device that includes a first transistor that includes a sidewall surrounding a side surface of the first transistor, a second transistor that is connected in series with the first transistor, and includes a sidewall surrounding a side surface of the second transistor, a first high-concentration diffusion layer that is provided on a semiconductor substrate and reaches a lower side of the sidewall on a drain side of the first transistor, and a third high-concentration diffusion layer that is provided on the semiconductor substrate between the first transistor and the second transistor and reaches a lower side of the side wall on a source side of the first transistor. The first high-concentration diffusion layer has a lower impurity concentration than the third high-concentration diffusion layer.

According to one aspect of the present disclosure, the solid-state imaging device has a first transistor that includes a sidewall surrounding a side surface of the first transistor, and a second transistor that is connected in series with the first transistor and includes a sidewall surrounding a side surface of the second transistor. A first high-concentration diffusion layer provided on a semiconductor substrate and reaching a lower side of the sidewall on a drain side of the first transistor has a lower impurity concentration than a third high-concentration diffusion layer provided on the semiconductor substrate between the first transistor and the second transistor and reaching a lower side of the sidewall on a source side of the first transistor.

### BRIEF DESCRIPTION OF DRAWINGS

FIG. 1 is a cross-sectional diagram illustrating a configuration example of an imaging device according to a first embodiment to which the present technology is applied.

FIG. 2 is a diagram explaining a manufacturing method of the imaging device in FIG. 1.

FIG. 3 is a diagram explaining the manufacturing method of the imaging device in FIG. 1.

FIG. 4 is a cross-sectional diagram illustrating a configuration example of an imaging device according to a second embodiment to which the present technology is applied.

FIG. 5 is a diagram explaining a manufacturing method of the imaging device in FIG. 4.

FIG. 6 is a cross-sectional diagram illustrating a configuration example of an imaging device according to a third embodiment to which the present technology is applied.

FIG. 7 is a diagram explaining a manufacturing method of the imaging device in FIG. 6.

FIG. 8 is a cross-sectional diagram illustrating a configuration example of an imaging device according to a fourth embodiment to which the present technology is applied.

FIG. 9 is a diagram explaining a manufacturing method of the imaging device in FIG. 8.

FIG. 10 is a diagram explaining a manufacturing method of the imaging device in FIG. 8.

FIG. 11 depicts diagrams illustrating an example of a planar layout of the imaging device in FIG. 1.

FIG. 12 is a diagram illustrating another example of the planar layout of the imaging device in FIG. 1.

FIG. 13 depicts diagrams illustrating an example of a planar layout of the imaging device in FIG. 6.

FIG. 14 depicts diagrams explaining a fin structure of transistors.

FIG. 15 depicts diagrams explaining a configuration example including two fins.

FIG. 16 is a diagram explaining cutting of gate electrodes.

FIG. 17 is a diagram explaining another example of a gate insulation film.

FIG. 18 depicts diagrams explaining wide contact electrodes.

FIG. 19 depicts diagrams explaining a configuration example including wide contact electrodes provided on the two fins.

FIG. 20 is a diagram illustrating an example of a pixel circuit diagram.

FIG. 21 is a block diagram illustrating a configuration example of an imaging apparatus.

FIG. 22 is a diagram illustrating use examples of an image sensor.

FIG. 23 is a block diagram depicting an example of schematic configuration of a vehicle control system.

FIG. 24 is a diagram of assistance in explaining an example of installation positions of an outside-vehicle information detecting section and an imaging section.

FIG. 25 is a diagram illustrating an example of a schematic configuration of an endoscope system.

FIG. 26 is a block diagram illustrating an example of a functional configuration of a camera and a camera control unit (CCU) illustrated in FIG. 25.

FIG. 27 is a diagram illustrating an example of a schematic configuration of a microscopic surgery system.

### DESCRIPTION OF EMBODIMENTS

Specific embodiments to which the present technology is applied will hereinafter be described in detail with reference to the drawings.

### First Configuration Example of Imaging Device

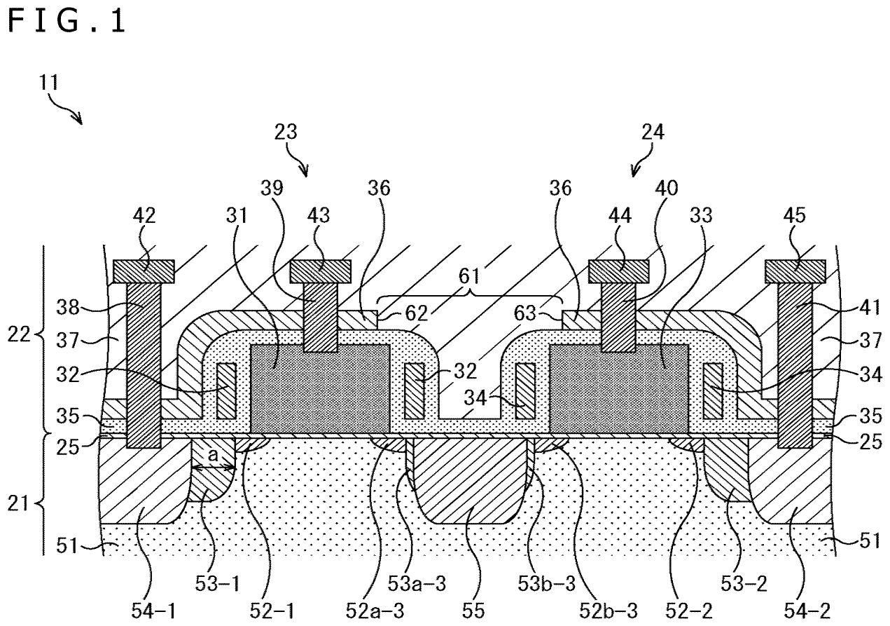

FIG. 1 is a cross-sectional diagram illustrating a configuration example of an imaging device according to a first embodiment to which the present technology is applied.

As illustrated in FIG. 1, an imaging device 11 includes a semiconductor substrate 21 and a wiring layer 22 laminated on the semiconductor substrate 21. Moreover, among a plurality of transistors provided for each of pixels equipped on the imaging device 11, FIG. 1 particularly illustrates a cross-sectional configuration example of an amplification transistor 23 and a selection transistor 24 connected in series. For example, according to the imaging device 11, the amplification transistor 23 amplifies charge photoelectrically converted by a photodiode, converts the charge into a pixel signal, and then outputs this pixel signal to a vertical signal line via the selection transistor 24.

A gate electrode 31 of the amplification transistor 23 and a gate electrode 33 of the selection transistor 24 are disposed on a surface of the semiconductor substrate 21 with a predetermined clearance left between the gate electrodes 31 and 33. Note that a gate insulation film 25 is formed on the surface of the semiconductor substrate 21. The gate insulation film 25 is configured to insulate the gate electrode 31 and the gate electrode 33 from the semiconductor substrate 21. For example, the gate insulation film 25 may be formed by oxidizing the surface of the semiconductor substrate 21, or by forming an Sio film, a high-dielectric insulation film, or the like on the surface of the semiconductor substrate 21.

Moreover, a sidewall 32 is so provided as to surround a side surface of the gate electrode 31, and a sidewall 34 is so provided as to surround a side surface of the gate electrode 33. Further, an oxide film (SiO) 35 constituting a buffer layer is so provided as to cover the gate electrode 31 and the sidewall 32 and further the gate electrode 33 and the sidewall 34. Further laminated on the oxide film 35 is a nitride film (SiN) 36 used as a stopper layer for etching of an interlayer film 37 of the wiring layer 22 that is performed at the time of formation of a contact electrode 38 connected to a second high-concentration diffusion layer 54-1, a contact electrode 39 connected to the gate electrode 31, a contact electrode 40 connected to the gate electrode 33, and a contact electrode 41 connected to a second high-concentration diffusion layer 54-2.

The wiring layer 22 includes the contact electrodes 38 through 41 and wires 42 through 45 within the interlayer film 37 laminated on the oxide film 35 and the nitride film 36. The wire 42 is connected to a drain of the amplification transistor 23 via the contact electrode 38 to supply a drain power source VDD to the amplification transistor 23. The wire 43 is connected to the gate electrode 31 via the contact electrode 39 to supply to the amplification transistor 23 potential of a level corresponding to charge transferred from the photodiode and accumulated in a floating diffusion section. The wire 44 is connected to the gate electrode 33 via the contact electrode 40 to supply a selection signal for controlling on-off of the selection transistor 24. The wire 45 is connected to a source of the selection transistor 24 via the contact electrode 41 to output a pixel signal to a vertical signal line.

For example, a low-concentration diffusion layer 52, a first high-concentration diffusion layer 53, a second high-concentration diffusion layer 54, and a third high-concentration diffusion layer 55, each formed by ion implantation of an N-type impurity into a P-type well layer 51, are provided on the semiconductor substrate 21. The low-concentration diffusion layer 52 is formed in a superficial region of the semiconductor substrate 21. The first high-concentration diffusion layer 53 is formed to reach a deep region of the semiconductor substrate 21. Each of the second high-concentration diffusion layer 54 and the third high-concentration diffusion layer 55 is formed to reach a deeper region of the semiconductor substrate 21 than the first high-concentration diffusion layer 53.

Provided on the drain side of the amplification transistor 23 are a low-concentration diffusion layer 52-1, a first high-concentration diffusion layer 53-1, and the second high-concentration diffusion layer 54-1 in this order from the vicinity of the gate electrode 31. Provided on the source side of the selection transistor 24 are a low-concentration diffusion layer 52-2, a first high-concentration diffusion layer 53-2, and the second high-concentration diffusion layer 54-2 in this order from the vicinity of the gate electrode 33. The third high-concentration diffusion layer 55 is provided between the amplification transistor 23 and the selection transistor 24. A low-concentration diffusion layer 52a-3 and a first high-concentration diffusion layer 53a-3 are provided in this order from the gate electrode 31 toward the third high-concentration diffusion layer 55, while a low-concentration diffusion layer 52b-3 and a first high-concentration diffusion layer 53b-3 are provided in this order from the gate electrode 33 to the third high-concentration diffusion layer 55.

The low-concentration diffusion layers 52-1 to 52-3 are LDD (Lightly Doped Drain) layers provided at ends of the gate electrode 31 and the gate electrode 33 to reduce an increase in electric field intensity in the vicinity of ends of the gate electrode 31 and the gate electrode 33 that occurs in association with miniaturization of the amplification transistor 23 and the selection transistor 24.

The first high-concentration diffusion layer 53-1 thus formed reduces electric field intensity between the low-concentration diffusion layer 52-1 and the second high-concentration diffusion layer 54-1 to have a lower impurity concentration than the second high-concentration diffusion layer 54-1. Moreover, as illustrated in the figure, the first high-concentration diffusion layer 53-1 is also formed on the lower side of the sidewall 32 on the drain side of the amplification transistor 23. Further, it is preferable that a width “a” of the first high-concentration diffusion layer 53-1, i.e., the distance between the low-concentration diffusion layer 52-1 and the second high-concentration diffusion layer 54-1, be set to at least 10 nm, for example.

The first high-concentration diffusion layer 53-2 thus formed reduces electric field intensity between the low-concentration diffusion layer 52-2 and the second high-concentration diffusion layer 54-2 to have a lower impurity concentration than the second high-concentration diffusion layer 54-2.

Each of the first high-concentration diffusion layers 53a-3 and 53b-3 is so provided as to have a lower impurity concentration than the third high-concentration diffusion layer 55. Alternatively, adoptable is such a configuration which eliminates the first high-concentration diffusion layers 53a-3 and 53b-3, i.e., such a configuration which includes the third high-concentration diffusion layer 55 extended to the region where the first high-concentration diffusion layers 53a-3 and 53b-3 are formed. In this case, a source side resistance value of the amplification transistor 23 decreases. Accordingly, gain characteristics of the amplification transistor 23 can improve.

The second high-concentration diffusion layer 54-1 is provided with a high impurity concentration necessary for forming a contact forming region provided for connection with the contact electrode 38. Similarly, the second high-concentration diffusion layer 54-2 is provided with a high impurity concentration necessary for forming a contact forming region provided for connection with the contact electrode 41.

The third high-concentration diffusion layer 55 is provided with a high impurity concentration necessary for appropriately reducing resistance of each of the gate electrode 31 of the amplification transistor 23 and the gate electrode 33 of the selection transistor 24. Moreover, as illustrated in the figure, the third high-concentration diffusion layer 55 is also formed on the lower side of the sidewall 32 on the source side of the amplification transistor 23.

For example, according to the imaging device 11, an opening 61 is formed in the nitride film 36 and opened between the gate electrode 31 of the amplification transistor 23 and the gate electrode 33 of the selection transistor 24. The nitride film 36 is formed such that the distance between an end surface 62 and an end surface 63 of the opening 61 becomes larger than the distance between the gate electrode 31 of the amplification transistor 23 and the gate electrode 33 of the selection transistor 24.

In addition, in a process for manufacturing the imaging device 11, performed is such a process which achieves ion implantation for forming the third high-concentration diffusion layer 55, by using, as a mask, the nitride film 36 including the opening 61 described above, in a step different from a process which achieves ion implantation for forming the second high-concentration diffusion layer 54-1. In such a manner, for example, the impurity concentration, the distribution, and the like of the third high-concentration diffusion layer 55 formed between the amplification transistor 23 and the selection transistor 24 can be determined according to desired designs while the impurity concentration, the distribution, and the like of the second high-concentration diffusion layer 54-1 provided on the drain side of the amplification transistor 23 are determined according to desired designs.

Specifically, the second high-concentration diffusion layer 54-1 is so designed as to have an impurity concentration necessary for forming the contact forming region provided for connection with the contact electrode 38 and that the first high-concentration diffusion layer 53-1 reaching a lower side of the sidewall 32 on the drain side of the amplification transistor 23 has a width of at least 10 nm. Moreover, the third high-concentration diffusion layer 55 is so designed as to have a high impurity concentration necessary for appropriately reducing resistance of each of the gate electrode 31 of the amplification transistor 23 and the gate electrode 33 of the selection transistor 24 and to reach a lower side of the sidewall 32 on the source side of the amplification transistor 23.

In such a manner, the imaging device 11 can be configured such that the first high-concentration diffusion layer 53-1 is provided on the lower side of the sidewall 32 on the drain side of the amplification transistor 23 and that the third high-concentration diffusion layer 55 is provided on the lower side of the sidewall 32 on the source side of the amplification transistor 23. In addition, the first high-concentration diffusion layer 53-1 is so designed as to have a lower impurity concentration than the third high-concentration diffusion layer 55. Accordingly, the imaging device 11 can offer advantageous effects of appropriate reduction of the drain side electric field and the contact resistance of the amplification transistor 23 and reduction of diffusion layer resistance between the amplification transistor 23 and the selection transistor 24. As a result, the imaging device 11 can improve aging deterioration of the amplification transistor 23 caused by hot carriers without reducing mutual conductance gm of the amplification transistor 23 and on-resistance Ron of the amplification transistor 23.

Further, the imaging device 11 can reduce an increase in the electric field intensity at the drain end of the amplification transistor 23 even when the width of the sidewall 32 is shortened in association with source follower miniaturization. In this case, source follower characteristics can improve.

Accordingly, the imaging device 11 can further raise performance by improvement of aging deterioration of the amplification transistor 23 caused by hot carriers, enhancement of source follower characteristics, and others.

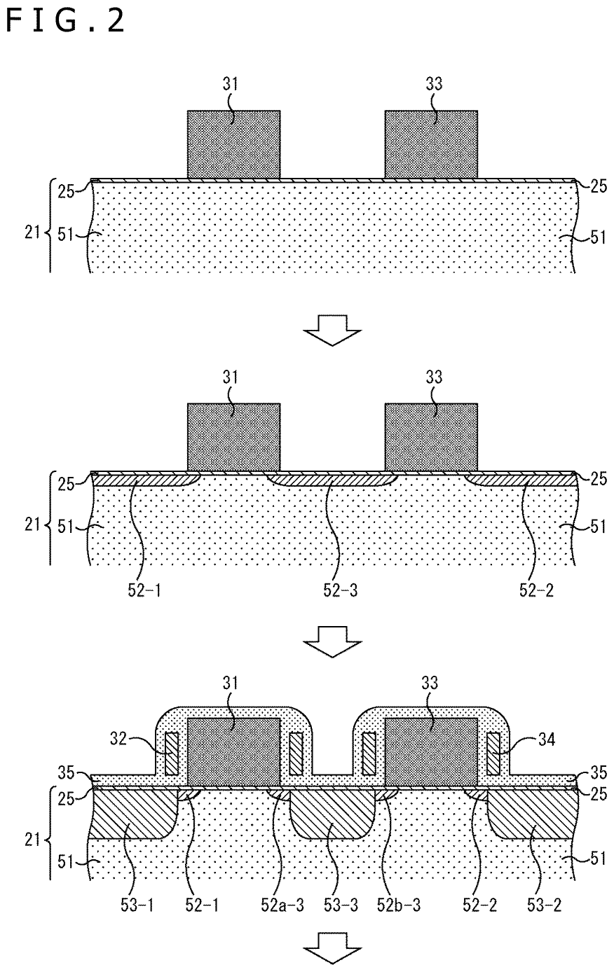

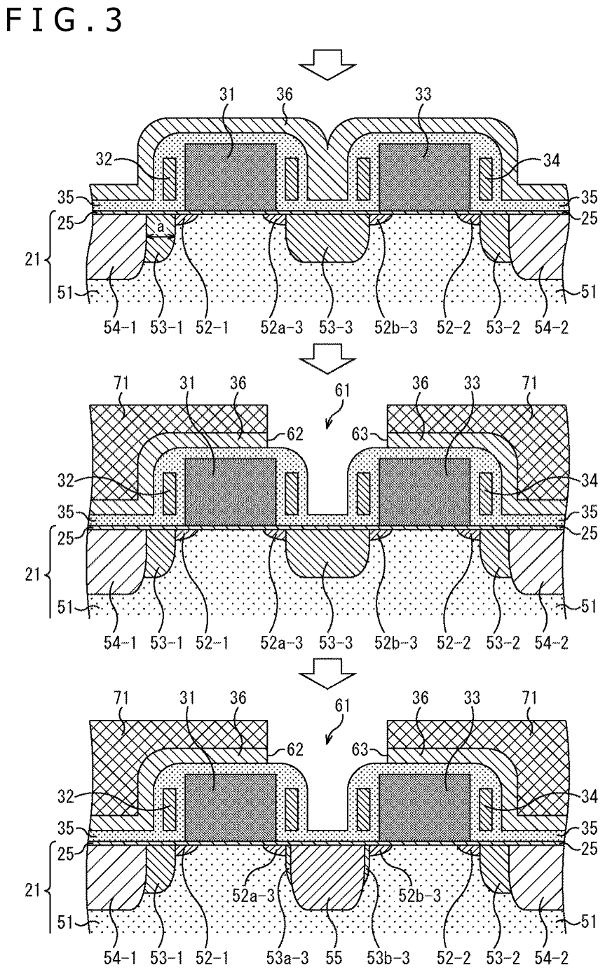

Described with reference to FIGS. 2 and 3 will be steps performed to form the amplification transistor 23 and the selection transistor 24 in the manufacturing method of the imaging device 11.

In a first step, as illustrated in a first stage of FIG. 2, the gate electrode 31 and the gate electrode 33 are formed with a predetermined clearance left therebetween by laminating polysilicon as an electrode material on the surface of the semiconductor substrate 21, for example.

In a second step, as illustrated in a second stage of FIG. 2, ion implantation (e.g., dose: 1E14 to 1E15) is carried out for a superficial region of the semiconductor substrate 21. In such a manner, the low-concentration diffusion layer 52-1 is formed on the drain side of the amplification transistor 23, the low-concentration diffusion layer 52-2 is formed on the source side of the selection transistor 24, and the low-concentration diffusion layer 52-3 is formed between the amplification transistor 23 and the selection transistor 24.

In a third step, as illustrated in a third stage of FIG. 2, the sidewall 32 is formed in such a manner as to surround the side surface of the gate electrode 31, and the sidewall 34 is formed in such a manner as to surround the side surface of the gate electrode 33. The oxide film 35 is further formed to cover the respective sidewalls 32 and 34. Thereafter, ion implantation (e.g., dose: 1E14 to 1E15) is carried out for a deep region of the semiconductor substrate 21. In such a manner, the first high-concentration diffusion layer 53-1 is formed on the drain side of the amplification transistor 23, the first high-concentration diffusion layer 53-2 is formed on the source side of the selection transistor 24, and the first high-concentration diffusion layer 53-3 is formed between the amplification transistor 23 and the selection transistor 24. At this time, ion implantation needs to be performed such that the first high-concentration diffusion layer 53-1 reaches the lower side of the sidewall 32 on the drain side of the amplification transistor 23.

In a fourth step, as illustrated in a first stage of FIG. 3, the nitride film 36 is laminated on the oxide film 35. Thereafter, ion implantation (e.g., dose: 2E15 to 8E15) is carried out up to a deep region of the semiconductor substrate 21 on the drain side of the gate electrode 31 and the source side of the gate electrode 33. In such a manner, the second high-concentration diffusion layer 54-1 is formed on the drain side of the amplification transistor 23, and the second high-concentration diffusion layer 54-2 is formed on the source side of the selection transistor 24. At this time, ion implantation for forming the second high-concentration diffusion layer 54-1 needs to be performed such that the first high-concentration diffusion layer 53-1 has the width “a” of at least 10 nm.

In a fifth step, as illustrated in a second stage of FIG. 3, a resist film 71 patterned to be opened in correspondence with the opening 61 is formed on the nitride film 36. Thereafter, the nitride film 36 formed between the amplification transistor 23 and the selection transistor 24 is removed by etching the nitride film 36 with use of the resist film 71 as a mask, to form the opening 61 in the nitride film 36.

In a sixth step, as illustrated in a third stage of FIG. 3, ion implantation (e.g., dose: 2E15 to 8E15) is carried out up to a deep region of the semiconductor substrate 21 between the gate electrode 31 and the gate electrode 33 with use of the nitride film 36 as a mask, to form the third high-concentration diffusion layer 55. At this time, ion implantation needs to be performed such that the third high-concentration diffusion layer 55 reaches the lower side of the sidewall 32 on the source side of the amplification transistor 23.

Thereafter, a process for removing the resist film 71 is performed, the interlayer film 37 is laminated, and a process for forming the contact electrodes 38 through 41 and the wires 42 through 45 within the interlayer film 37 is further performed to form the wiring layer 22. In this manner, the amplification transistor 23 and the selection transistor 24 illustrated in FIG. 1 are completed.

As apparent from above, forming the second high-concentration diffusion layers 54-1 and 24-2 and the third high-concentration diffusion layer 55 in different steps makes it possible to carry out ion implantation in different conditions. In such a manner, the second high-concentration diffusion layers 54-1 and 24-2 and the third high-concentration diffusion layer 55 can be formed with different impurity designs. For example, each of the second high-concentration diffusion layers 54-1 and 24-2 is allowed to maintain an impurity concentration necessary for forming the contact forming region, while the third high-concentration diffusion layer 55 is allowed to have an impurity concentration for lowering electric field intensity of the region formed between the amplification transistor 23 and the selection transistor 24. In such a manner, the imaging device 11 can improve source follower characteristics of the amplification transistor 23 and the selection transistor 24.

### Second Configuration Example of Imaging Device

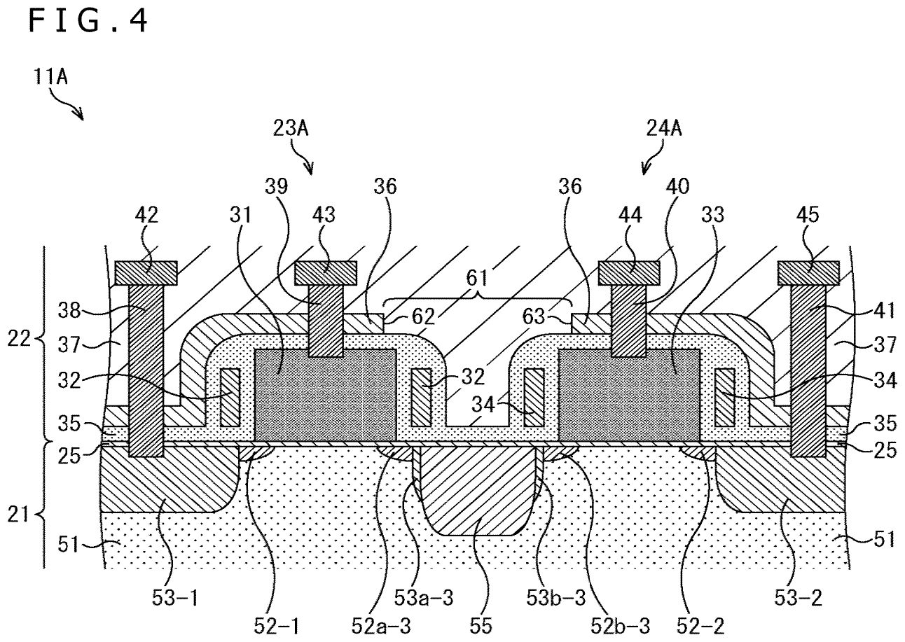

FIG. 4 is a cross-sectional diagram illustrating a configuration example of an imaging device according to a second embodiment to which the present technology is applied. Note that constituent elements included in an imaging device 11A in FIG. 4 and identical to the corresponding constituent elements of the imaging device 11 in FIG. 1 are given identical reference signs, and will not repeatedly be explained in detail.

As illustrated in FIG. 4, the imaging device 11A includes an amplification transistor 23A and a selection transistor 24A similarly to the imaging device 11 in FIG. 1.

However, the imaging device 11A has a configuration different from the configuration of the imaging device 11 in FIG. 1 in that the amplification transistor 23A does not have the second high-concentration diffusion layer 54-1 provided on the drain side of the amplification transistor 23 in FIG. 1 and that the amplification transistor 23A does not have the second high-concentration diffusion layer 54-2 provided on the source side of the selection transistor 24 in FIG. 1. Accordingly, in the case of the imaging device 11A, the first high-concentration diffusion layer 53-1 is used as a contact forming region for connection with the contact electrode 38, and the first high-concentration diffusion layer 53-2 is used as a contact forming region for connection with the contact electrode 41.

In other words, the imaging device 11A has such a structure where the contact forming region for connection with the contact electrode 38 on the drain side of the amplification transistor 23A has an impurity concentration lower than that of the imaging device 11 in FIG. 1.

Similarly to the imaging device 11 in FIG. 1, the imaging device 11A configured as above can further raise performance by improvement of aging deterioration of the amplification transistor 23A caused by hot carriers, enhancement of source follower characteristics, and others.

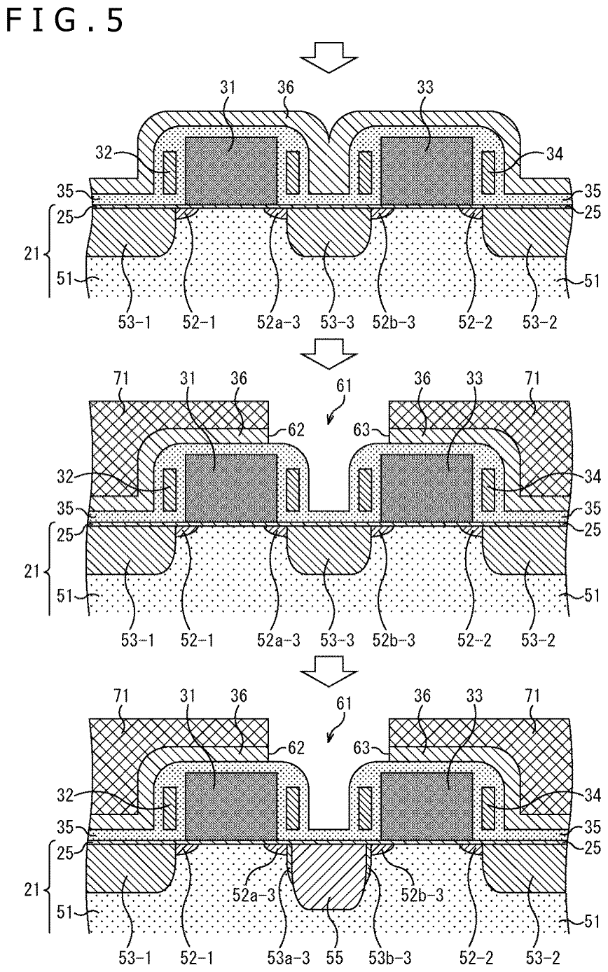

Described with reference to FIG. 5 will be steps for forming the amplification transistor 23A and the selection transistor 24A in the manufacturing method of the imaging device 11A.

First, processes similar to the first to third steps explained above with reference to FIG. 2 are executed, and then an 11th step is performed.

In the 11th step, as illustrated in a first stage of FIG. 5, the nitride film 36 is laminated on the oxide film 35. In this case, while the second high-concentration diffusion layers 54-1 and 54-2 are formed in the fourth step described above with reference to FIG. 3, the second high-concentration diffusion layers 54-1 and 54-2 are not formed in the 11th step.

Subsequently, in 12th and 13th steps, a process for forming the opening 61 in the nitride film 36 and a process for forming the third high-concentration diffusion layer 55 with use of the nitride film 36 as a mask are performed as in the fifth and sixth steps explained above with reference to FIG. 3. Thereafter, a process for removing the resist film 71 is performed, the interlayer film 37 is laminated, and a process for forming the contact electrodes 38 through 41 and the wires 42 through 45 within the interlayer film 37 is further performed to form the wiring layer 22. In this manner, the amplification transistor 23A and the selection transistor 24A illustrated in FIG. 4 are completed.

### Third Configuration Example of Imaging Device

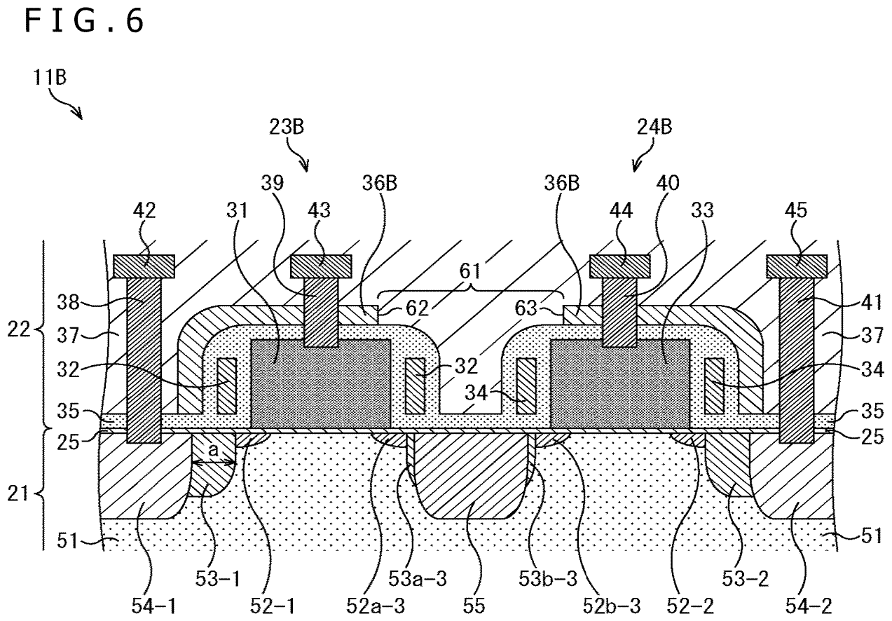

FIG. 6 is a cross-sectional diagram illustrating a configuration example of an imaging device according to a third embodiment to which the present technology is applied. Note that constituent elements included in an imaging device 11B in FIG. 6 and identical to the corresponding constituent elements of the imaging device 11 in FIG. 1 are given identical reference signs, and will not repeatedly be explained in detail.

As illustrated in FIG. 6, the imaging device 11B includes an amplification transistor 23B and a selection transistor 24B similarly to the imaging device 11 in FIG. 1.

However, the imaging device 11B has a configuration different from the configuration of the imaging device 11 in FIG. 1 in that a nitride film 36B is not formed on the drain side of the amplification transistor 23B and the source side of the selection transistor 24B. Specifically, in the case of the configuration of the imaging device 11B, the opening 61 is formed in the nitride film 36B located between the amplification transistor 23B and the selection transistor 24B. In addition, the nitride film 36B is formed up to the side surface of the sidewall 32 on the drain side of the amplification transistor 23B, and the nitride film 36B is formed up to the side surface of the sidewall 34 on the source side of the selection transistor 24B.

Similarly to the imaging device 11 in FIG. 1, the imaging device 11B configured as above can further raise performance by improvement of aging deterioration of the amplification transistor 23B caused by hot carriers, enhancement of source follower characteristics, and others.

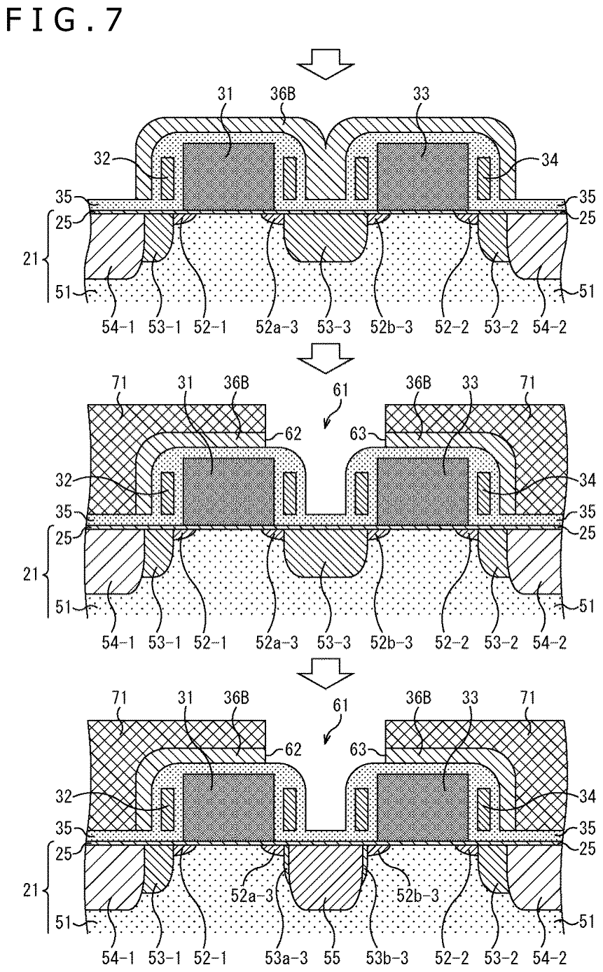

Described with reference to FIG. 7 will be steps for forming the amplification transistor 23B and the selection transistor 24B in the manufacturing method of the imaging device 11B.

First, processes similar to the first to third steps explained above with reference to FIG. 2 are executed, and then a 21st step is performed.

In the 21st step, as illustrated in a first stage of FIG. 7, the nitride film 36B is laminated on the oxide film 35, and then the nitride film 36B formed on the surface of the semiconductor substrate 21 is etched back on the drain side of the amplification transistor 23B and the source side of the selection transistor 24B. In such a manner, the nitride film 36B on the drain side of the amplification transistor 23B and the nitride film 36B on the source side of the selection transistor 24B are removed. Thereafter, ion implantation (e.g., dose: 2E15 to 8E15) is carried out up to a deep region of the semiconductor substrate 21 on the drain side of the gate electrode 31 and the source side of the gate electrode 33 to form the second high-concentration diffusion layers 54-1 and 54-2.

Subsequently, in 22nd and 23rd steps, a process for forming the opening 61 in the nitride film 36 and a process for forming the third high-concentration diffusion layer 55 with use of the nitride film 36 as a mask are performed as in the fifth and sixth steps explained above with reference to FIG. 3. Thereafter, a process for removing the resist film 71 is performed, the interlayer film 37 is laminated, and a process for forming the contact electrodes 38 through 41 and the wires 42 through 45 within the interlayer film 37 is further performed. In this manner, the amplification transistor 23B and the selection transistor 24B illustrated in FIG. 6 are completed.

### Fourth Configuration Example of Imaging Device

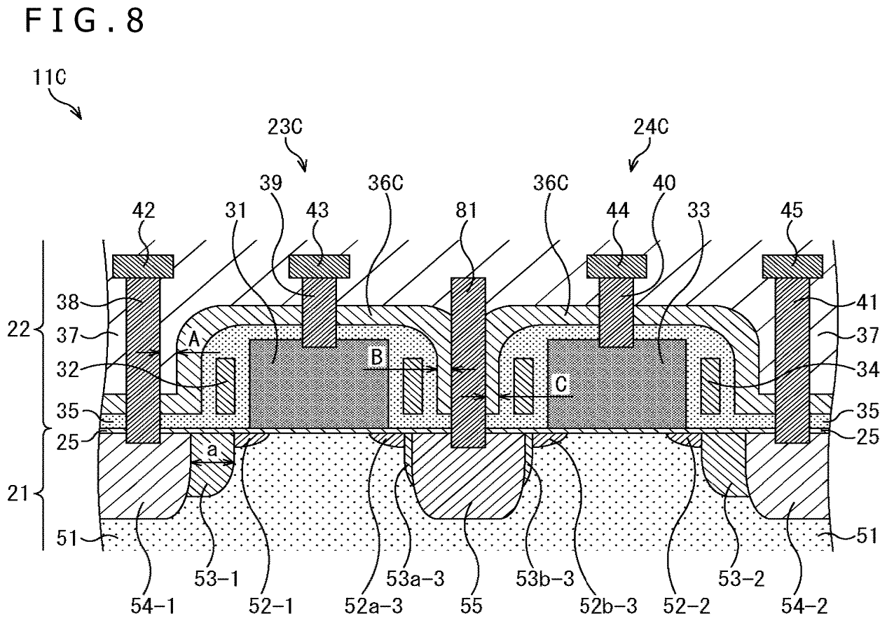

FIG. 8 is a cross-sectional diagram illustrating a configuration example of an imaging device according to a fourth embodiment to which the present technology is applied. Note that constituent elements included in an imaging device 11C in FIG. 8 and identical to the corresponding constituent elements of the imaging device 11 in FIG. 1 are given identical reference signs, and will not repeatedly be explained in detail.

As illustrated in FIG. 8, the imaging device 11C includes an amplification transistor 23C and a selection transistor 24C similarly to the imaging device 11 in FIG. 1.

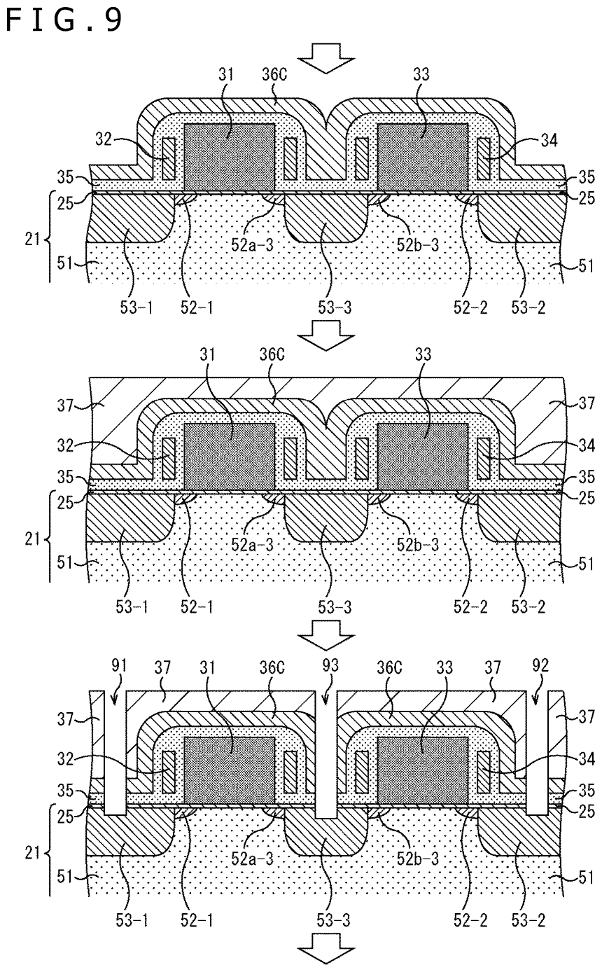

However, the imaging device 11C has a configuration different from the configuration of the imaging device 11 in FIG. 1 in that the opening 61 (FIG. 1) is not formed in a nitride film 36C and that a pseudo contact electrode 81 is provided between the amplification transistor 23C and the selection transistor 24C. Specifically, the imaging device 11C has such a structure which includes a through hole 93 (see FIG. 9) in the interlayer film 37 as a hole for forming the third high-concentration diffusion layer 55. According to this structure, the third high-concentration diffusion layer 55 is formed by ion implantation using the through hole 93. After the third high-concentration diffusion layer 55 is formed, a metal material such as tungsten is embedded into the through hole 93, for example, in the step for forming the contact electrodes 38 through 41, to produce the pseudo contact electrode 81.

Moreover, the pseudo contact electrode 81 is configured such that one end is connected to the semiconductor substrate 21, and that the other end is not connected (not connected to the wires 42 through 45 unlike the contact electrodes 38 through 41). In this case, the pseudo contact electrode 81 is in an electrically floating state. Accordingly, parasitic capacitance is not raised by the presence of the pseudo contact electrode 81 which is in the electrically floating state.

Moreover, in the case of the imaging device 11C, the width “a” of the first high-concentration diffusion layer 53-1, i.e., the distance between the low-concentration diffusion layer 52-1 and the second high-concentration diffusion layer 54-1, is adjustable by adjustment of a distance A between the contact electrode 38 and the nitride film 36C. As described above, it is preferable that the width “a” of the first high-concentration diffusion layer 53-1 be set to at least 10 nm, for example.

Further, in the case of the imaging device 11C, a distance B between the pseudo contact electrode 81 and the nitride film 36C on the amplification transistor 23C side and a distance C between the pseudo contact electrode 81 and the nitride film 36C on the selection transistor 24C side may be equalized (B=C). For example, in the case where the distance B and the distance C are equalized, each of the distance B and the distance C is controlled by the radius of the pseudo contact electrode 81.

Alternatively, the distance B between the pseudo contact electrode 81 and the nitride film 36C on the amplification transistor 23C side may be smaller than the distance C between the pseudo contact electrode 81 and the nitride film 36C on the selection transistor 24C side (B<C). For example, in the case where the distance B is smaller than the distance C, each of the distance B and the distance C is controlled by the radius and the arrangement position of the pseudo contact electrode 81.

In addition, in a case where the distance B is larger than or equal to the distance C (B≥C), resistance on the source side of the amplification transistor 23C increases, and an electric field on the drain side of the selection transistor 24C increases, which is unpreferable.

Similarly to the imaging device 11 in FIG. 1, the imaging device 11C configured as above can further raise performance by improvement of aging deterioration of the amplification transistor 23C caused by hot carriers, enhancement of source follower characteristics, and others.

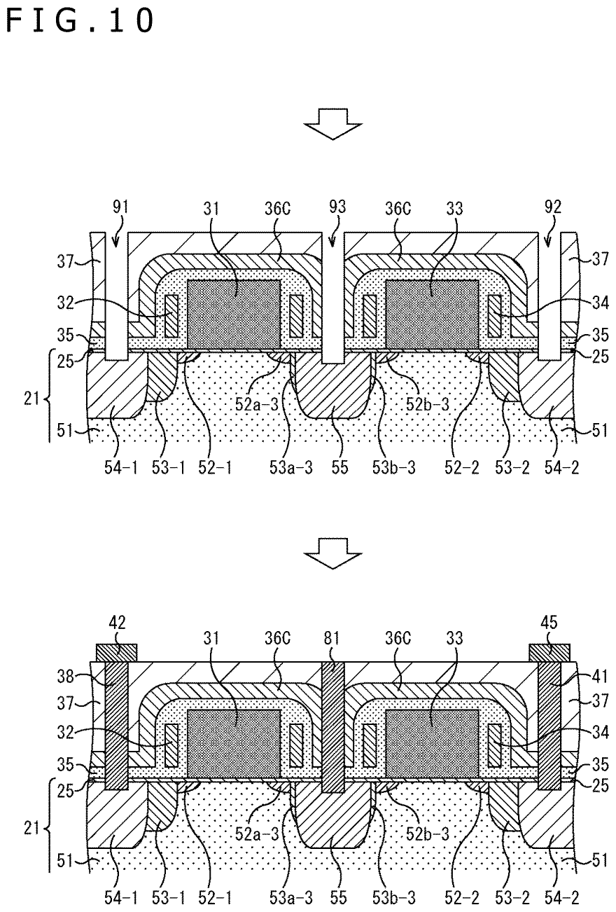

Described with reference to FIGS. 9 and 10 will be steps for forming the amplification transistor 23C and the selection transistor 24C in the manufacturing method of the imaging device 11C.

First, processes similar to the first to third steps explained above with reference to FIG. 2 are executed, and then a 31st step is performed.

In the 31st step, as illustrated in a first stage of FIG. 9, the nitride film 36C is laminated on the oxide film 35.

In a 32nd step, as illustrated in a second stage of FIG. 9, the interlayer film 37 is laminated on the nitride film 36C with a thickness corresponding to each length of the contact electrodes 38 and 41 and the pseudo contact electrode 81.

In a 33rd step, as illustrated in a third stage of FIG. 9, through holes 91 through 93 are formed to penetrate the interlayer film 37. The through hole 91 is so formed as to open the first high-concentration diffusion layer 53-1, the through hole 92 is so formed as to open the first high-concentration diffusion layer 53-2, and the through hole 93 is so formed as to open the first high-concentration diffusion layer 53-3.

In a step in FIG. 34, as illustrated in a first stage of FIG. 10, ion implantation (e.g., dose: 2E15 to 8E15) is carried out up to a deep region of the semiconductor substrate 21 using the through holes 91 through 93, to form the second high-concentration diffusion layers 54-1 and 54-2 and the third high-concentration diffusion layer 55.

In a step in FIG. 35, as illustrated in a second stage of FIG. 10, a metal material such as tungsten is embedded into the through holes 91 through 93 to form the contact electrodes 38 and 41 and the pseudo contact electrode 81. Moreover, the wire 42 connecting with the contact electrode 38 and the wire 45 connecting with the contact electrode 41 are formed.

Thereafter, a process for forming the contact electrodes 39 and 40 and the wires 43 and 44 and further laminating the interlayer film 37 is performed to form the wiring layer 22. In this manner, the amplification transistor 23C and the selection transistor 24C illustrated in FIG. 8 are completed.

Note that the imaging device 11C may have such a configuration produced by embedding the same material as the material of the interlayer film 37 into the through hole 92 after the third high-concentration diffusion layer 55 is formed, instead of the configuration including the pseudo contact electrode 81.

### Planar Layout of Imaging Device

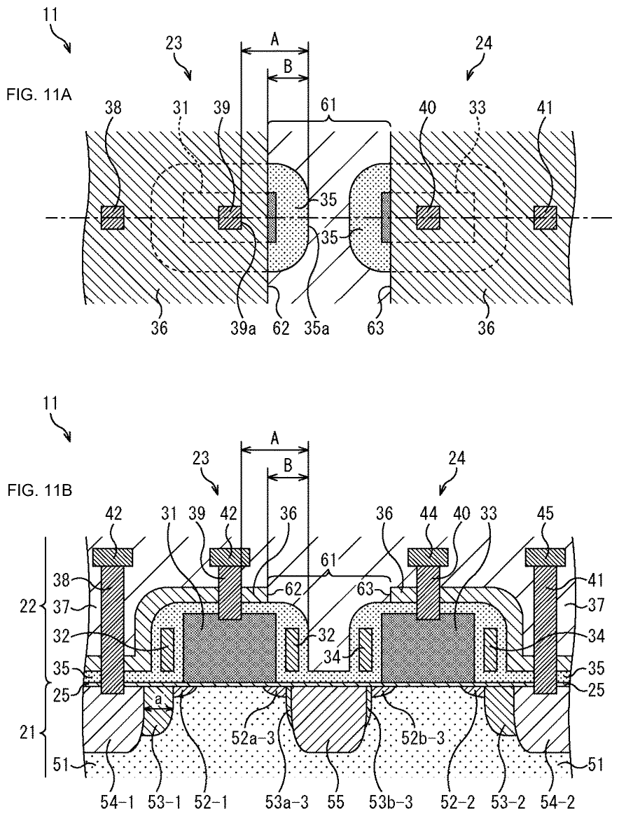

A planar layout of the imaging device 11 will be described with reference to FIGS. 11 through 13.

A of FIG. 11 illustrates an example of a planar layout of the imaging device 11, while B of FIG. 11 illustrates a cross-sectional configuration example of the imaging device 11 similar to that of the imaging device 11 illustrated in FIG. 1.

As illustrated in A of FIG. 11, the imaging device 11 may adopt such a planar layout which includes the amplification transistor 23 and the selection transistor 24 each linearly arranged in a planar view. Specifically, as indicated by a one-dot chain line in the figure, the amplification transistor 23 and the selection transistor 24 are arranged such that a line connecting the source and the drain of the amplification transistor 23 and a line connecting the source and the drain of the selection transistor 24 form one straight line.

Moreover, for example, a distance A indicated in FIG. 11 is a distance between a side surface 39a, which is included in side surfaces of the contact electrode 39 connected to the gate electrode 31 of the amplification transistor 23 and which is facing the selection transistor 24, and a reference, which is set to a side surface 35a that is included in side surfaces of the oxide film 35 covering the sidewall 32 of the amplification transistor 23 and that is facing the selection transistor 24. Further, for example, a distance B indicated in FIG. 11 is a distance between an end surface 62 of the opening 61 of the nitride film 36 covering the amplification transistor 23 and the reference which is set to the side surface 35a that is included in the side surfaces of the oxide film 35 covering the sidewall 32 of the amplification transistor 23 and that is facing the selection transistor 24.

For example, the imaging device 11 is required to have the nitride film 36 existing in a region where the contact electrode 39 is connected to the gate electrode 31, for the purpose of reducing an excavation amount of the gate electrode 31 during processing for the contact electrode 39, i.e., providing a countermeasure for plasma damage (PID: Plasma Induced Damage) for the gate electrode 31. Accordingly, in the case of the imaging device 11, the distance A between the side surface 39a of the contact electrode 39 and the reference set to the side surface 35a of the oxide film 35 needs to be larger than or equal to the distance B between the end surface 62 of the opening 61 and the reference set to the side surface 35a of the oxide film 35 (A≥B).

Moreover, as illustrated in B of FIG. 11, the imaging device 11 includes the first high-concentration diffusion layer 53-1 on the lower side of the sidewall 32 on the drain side of the amplification transistor 23 and the third high-concentration diffusion layer 55 on the lower side of the sidewall 32 on the source side of the amplification transistor 23. In addition, as described above, the first high-concentration diffusion layers 53-1 is so formed as to have a lower impurity concentration than the third high-concentration diffusion layer 55. Specifically, the imaging device 11 is configured such that the impurity concentration on the lower side of the sidewall 32 on the drain side of the amplification transistor 23 is lower than the impurity concentration on the lower side of the sidewall 32 on the source side of the amplification transistor 23.

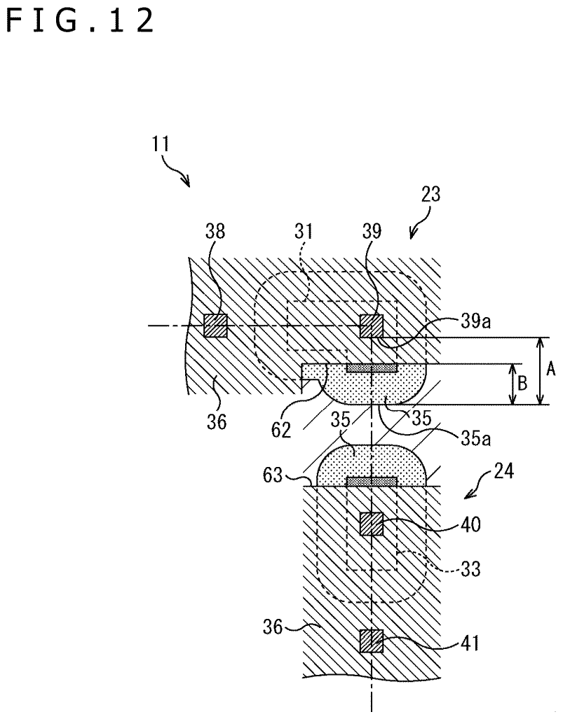

FIG. 12 illustrates another example of a planar layout of the imaging device 11.

As illustrated in FIG. 12, the imaging device 11 can adopt such a planar layout which includes the amplification transistor 23 and the selection transistor 24 crossing each other substantially at right angles and forming an L shape in a planar view. Specifically, as indicated by a one-dot chain line in the figure, the amplification transistor 23 and the selection transistor 24 are arranged such that a line extending from the gate electrode 31 to the source of the amplification transistor 23, and a line extending from the gate electrode 31 to the drain of the amplification transistor 23 and connecting the source and the drain of the selection transistor 24 cross each other substantially at right angles.

As in the configuration explained with reference to FIG. 11, in the case of the imaging device 11 having the foregoing planar layout, the distance A between the side surface 39a of the contact electrode 39 and the reference set to the side surface 35a of the oxide film 35 needs to be larger than or equal to the distance B between the end surface 62 of the opening 61 and the reference set to the side surface 35a of the oxide film 35 (A≥B).

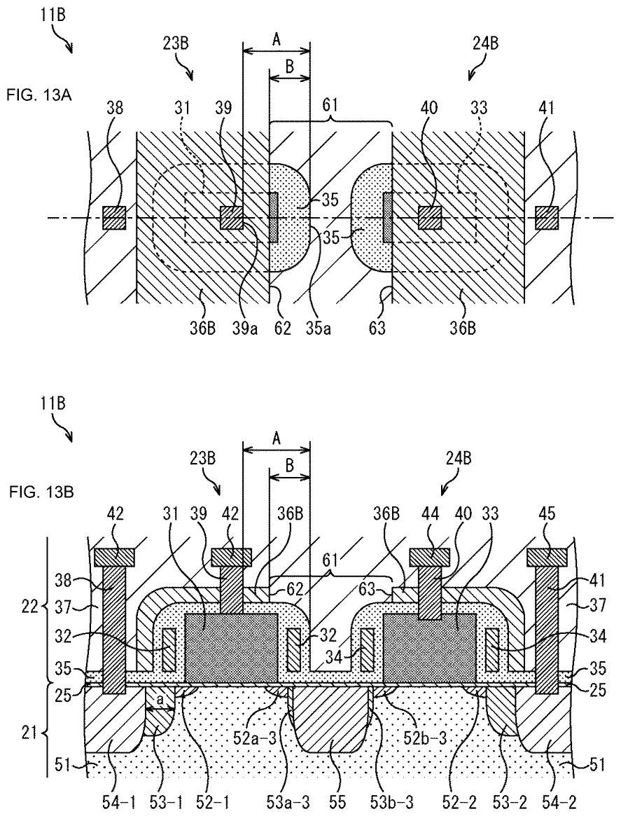

A of FIG. 13 illustrates an example of the planar layout of the imaging device 11B, while B of FIG. 13 illustrates a cross-sectional configuration example of the imaging device 11B similar to the configuration illustrated in FIG. 6.

As illustrated in A of FIG. 13, the imaging device 11B may adopt such a planar layout which includes the amplification transistor 23B and the selection transistor 24B arranged in a straight line.

In addition, in the case of the imaging device 11B, as in the configuration explained with reference to FIG. 11, the distance A between the side surface 39a of the contact electrode 39 and the reference set to the side surface 35a of the oxide film 35 needs to be larger than or equal to the distance B between the end surface 62 of the opening 61 and the reference set to the side surface 35a of the oxide film 35 (A≥B).

### Fin Structure of Transistor

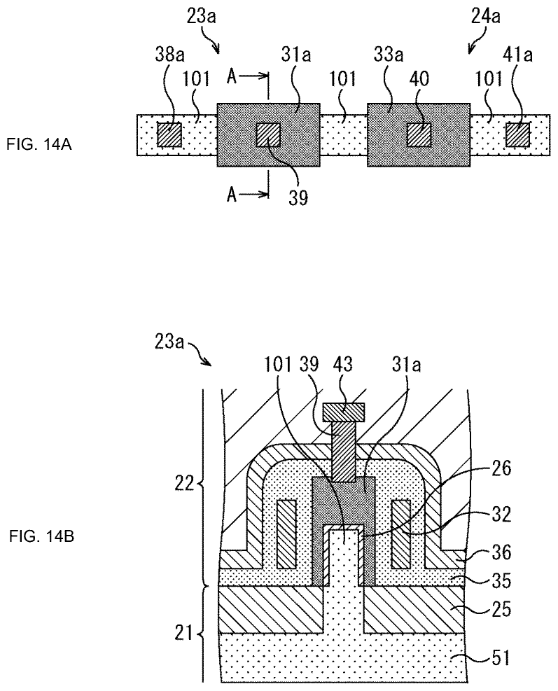

Described with reference to FIG. 14 will be an amplification transistor 23a and a selection transistor 24a each adopting a fin structure.

A of FIG. 14 illustrates an example of a planar layout of the amplification transistor 23a and the selection transistor 24a each adopting the fin structure, while B of FIG. 14 illustrates a cross-sectional configuration of the amplification transistor 23a viewed in a direction of arrows A-A indicated in A of FIG. 14. Note that the selection transistor 24a has a cross-sectional configuration similar to the cross-sectional configuration of the amplification transistor 23a.

For example, the imaging device 11 may have such a configuration which includes the amplification transistor 23a and the selection transistor 24a each having a three-dimensional fin structure equipped with fins 101 provided from the drain side of the amplification transistor 23a to the source side of the selection transistor 24a and each shaped to protrude with respect to the semiconductor substrate 21. As illustrated in B of FIG. 14, each of the fins 101 has a protruding shape having a part of the semiconductor substrate 21 protruding toward the wiring layer 22, and is insulated from the gate electrode 31a by a gate insulation film 26 which covers a protruding portion of the fin 101 from the gate insulation film 25 planarly formed on the surface of the semiconductor substrate 21.

Each of the amplification transistor 23a and the selection transistor 24a adopting such a fin structure obtains such characteristics as a shorter switching time and higher current density. While FIG. 14 illustrates a configuration example including one fin 101, a configuration including a plurality of fins 101 may be adopted to further improve the characteristics of the amplification transistor 23a and the selection transistor 24a.

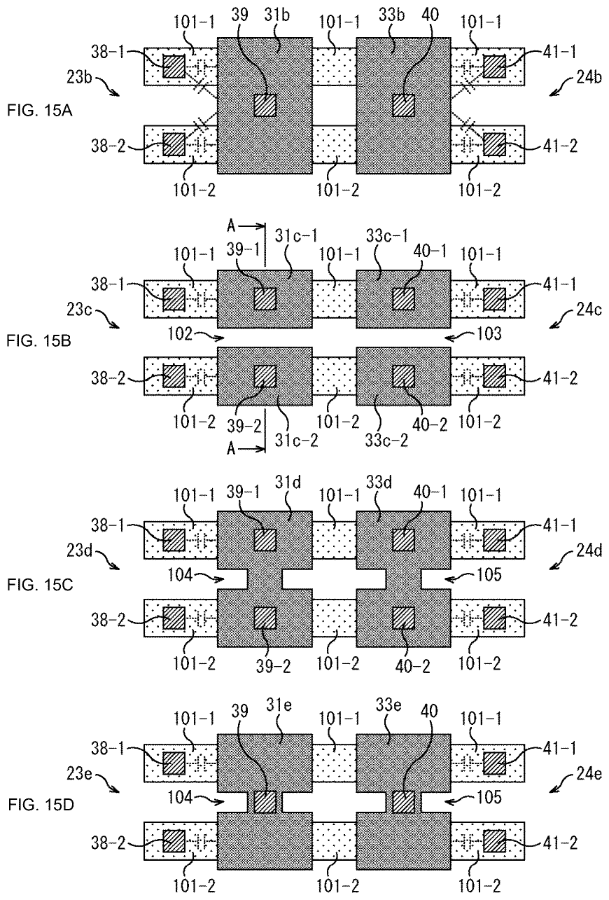

A configuration example which includes two fins 101-1 and 101-2 will be described with reference to FIG. 15.

A of FIG. 15 illustrates a configuration example which includes an amplification transistor 23b having a gate electrode 31b and a selection transistor 24b having a gate electrode 33b. The gate electrode 31b and the gate electrode 33b are so provided as to cross over the fin 101-1 and the fin 101-2. Each of the amplification transistor 23b and the selection transistor 24b adopting such a configuration obtains such characteristics as a further shorter switching time and further higher current density than those characteristics of the amplification transistor 23a and the selection transistor 24a in FIG. 14.

Meanwhile, as indicated by broken lines in the figure, parasitic capacitance generated between the gate electrode 31b and contact electrodes 38-1 and 38-2 increases in the amplification transistor 23b in association with an increase in a side area of the gate electrode 31b. Similarly, as indicated by broken lines in the figure, parasitic capacitance generated between the gate electrode 33b and contact electrodes 41-1 and 41-2 increases in the selection transistor 24b in association with an increase in a side area of the gate electrode 33b. It is therefore considered to be preferable to adopt such a configuration capable of reducing parasitic capacitance.

B of FIG. 15 illustrates a configuration example which includes an amplification transistor 23c which has gate electrodes 31c-1 and 31c-2 provided on the fin 101-1 and the fin 101-2, respectively, and a selection transistor 24c which has gate electrodes 33c-1 and 33c-2 provided on the fin 101-1 and the fin 101-2, respectively. Accordingly, a slit 102 is provided between the gate electrode 31c-1 and the gate electrode 31c-2, while a slit 103 is provided between the gate electrode 33c-1 and the gate electrode 33c-2. In other words, in the case of the amplification transistor 23c and the selection transistor 24c, the gate electrode 31c-1 and the gate electrode 33c-1 are provided for the fin 101-1, while the gate electrode 31c-2 and the gate electrode 33c-2 are provided for the fin 101-2.

The amplification transistor 23c and the selection transistor 24c configured as above have a smaller side area than the amplification transistor 23b and the selection transistor 24b, and therefore can reduce parasitic capacitance.

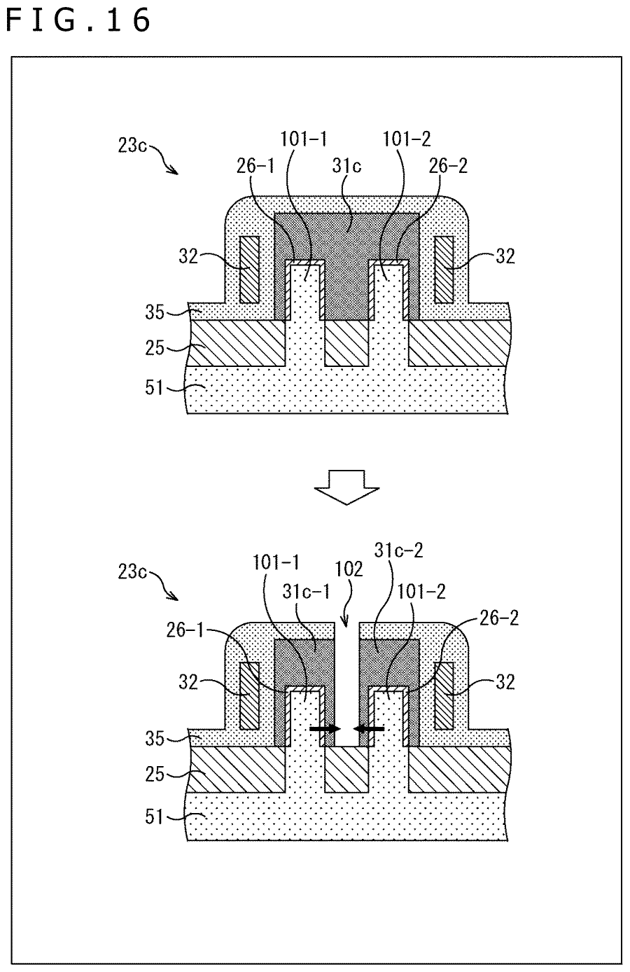

For example, as illustrated in FIG. 16, the gate electrode 31c-1 and the gate electrode 31c-2 of the amplification transistor 23c can be formed by forming the gate electrode 31c which crosses over the fin 101-1 and the fin 101-2 and then cutting the gate electrode 31c along a cutting position between the fin 101-1 and the fin 101-2. Similarly, while not illustrated in the figure, the gate electrode 33c-1 and the gate electrode 33c-2 of the selection transistor 24c can be formed by forming the gate electrode 33c which crosses over the fin 101-1 and the fin 101-2 and then cutting the gate electrode 33c along a cutting position between the fin 101-1 and the fin 101-2. Note that the gate electrode 31c and the gate electrode 33c may be cut at the time of formation of the respective gate electrodes 31c and 33c, or after lamination of the interlayer film 37.

Tensile stress can be applied to a channel as indicated by a thick arrow in FIG. 16 by forming the slit 102 between the gate electrode 31c-1 and the gate electrode 31c-2 (similarly, by forming the slit 103 between the gate electrode 33c-1 and the gate electrode 33c-2) as described above. This configuration of the amplification transistor 23c and the selection transistor 24c is therefore expected to improve electron mobility.

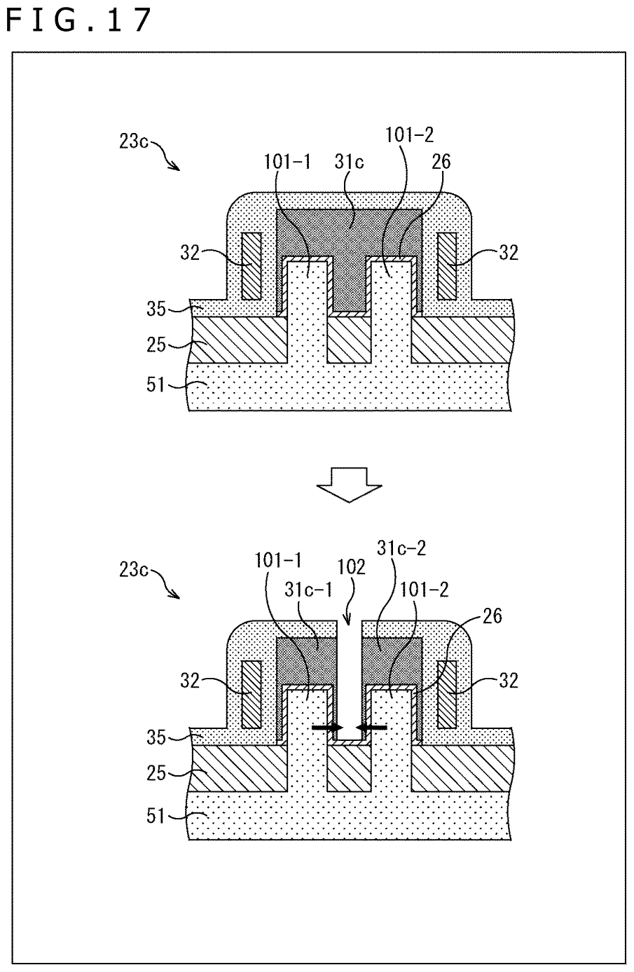

Note that FIG. 16 illustrates a configuration example which forms the gate insulation film 26 by oxidizing surfaces of the fin 101-1 and the fin 101-2 at portions protruding from the gate insulation film 25 planarly provided on the surface of the semiconductor substrate 21. Meanwhile, FIG. 17 illustrates a configuration example which forms the gate insulation film 26 by forming an SiO film, a high-dielectric insulation film, or the like on the surfaces of the fin 101-1 and the fin 101-2 at the portions protruding from the gate insulation film 25 planarly provided on the surface of the semiconductor substrate 21.

C of FIG. 15 illustrates a configuration example which includes an amplification transistor 23d having a gate electrode 31d containing a cut 104 and a selection transistor 24d having a gate electrode 33d containing a cut 105. The gate electrode 31d and the gate electrode 33d are so provided as to cross over the fin 101-1 and the fin 101-2.

For example, the cut 104 is formed in both side surfaces of the gate electrode 31d of the amplification transistor 23d between the fin 101-1 and the fin 101-2, and a contact electrode 39-1 and a contact electrode 39-2 are connected to the gate electrode 31d in correspondence with the fin 101-1 and the fin 101-2, respectively. Similarly, the cut 105 is formed in both side surfaces of the gate electrode 33d of the selection transistor 24d between the fin 101-1 and the fin 101-2, and a contact electrode 40-1 and a contact electrode 40-2 are connected to the gate electrode 33d in correspondence with the fin 101-1 and the fin 101-2, respectively.

The amplification transistor 23d and the selection transistor 24d configured as above have smaller side areas than the amplification transistor 23b and the selection transistor 24b, and therefore can reduce parasitic capacitance.

D of FIG. 15 illustrates a configuration example which includes an amplification transistor 23e having a gate electrode 31e containing the cut 104 and a selection transistor 24e having a gate electrode 33e containing the cut 105. The gate electrode 31e and the gate electrode 33e are so provided as to cross over the fin 101-1 and the fin 101-2.

For example, the cut 104 is formed in both side surfaces of the gate electrode 31e of the amplification transistor 23e between the fin 101-1 and the fin 101-2, and a contact electrode 39 is connected to the center of the gate electrode 31e. Similarly, the cut 105 is formed in both side surfaces of the gate electrode 33e of the selection transistor 24e between the fin 101-1 and the fin 101-2, and a contact electrode 40 is connected to the center of the gate electrode 33e.

The amplification transistor 23e and the selection transistor 24e configured as above have smaller side areas than the amplification transistor 23b and the selection transistor 24b, and therefore can reduce parasitic capacitance.

While FIG. 15 illustrates the configuration example which includes the two fins 101-1 and 101-2, a configuration which includes two or more fins 101 may be adopted.

### Structure of Wide Contact Electrode

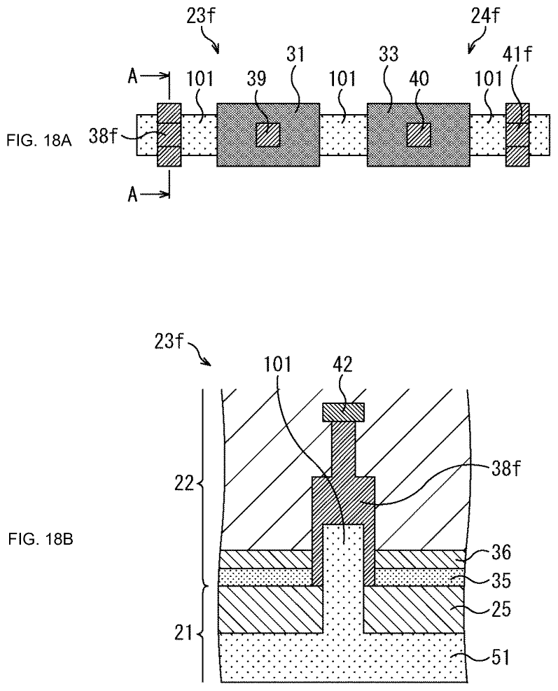

Described with reference to FIG. 18 will be an amplification transistor 23f and a selection transistor 24f each adopting a wide contact electrode. Note that each of the amplification transistor 23f and the selection transistor 24f has the fin structure similarly to the amplification transistor 23a and the selection transistor 24a described above with reference to FIG. 14.

A of FIG. 18 illustrates an example of a planar layout of the amplification transistor 23f adopting a wide contact electrode 38f and the selection transistor 24f adopting a wide contact electrode 41f. B of FIG. 18 illustrates a cross-sectional configuration of the wide contact electrode 38f viewed in a direction of arrows A-A in A of FIG. 18. Note that the wide contact electrode 41f has a cross-sectional configuration similar to the cross-sectional configuration of the wide contact electrode 38f.

For example, as illustrated in B of FIG. 18, the amplification transistor 23f is formed such that the contact electrode 38f has a wide shape sufficient for producing such a structure which brings the wide contact electrode 38f and the fin 101 into contact with each other not only on the upper surface of the fin 101, but also on the side surface of the fin 101. Accordingly, the amplification transistor 23f can lower resistance in association with an increase in the contact area between the wide contact electrode 38f and the fin 101. Similarly, the selection transistor 24f can lower resistance in association with an increase in the contact area between the wide contact electrode 41f and the fin 101.

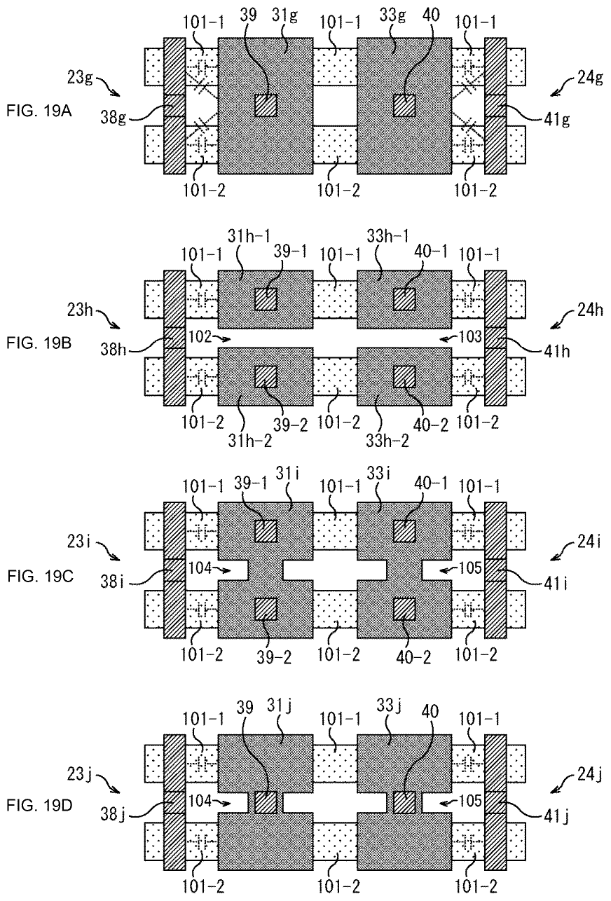

Described with reference to FIG. 19 will be a configuration example which includes wide contact electrodes respectively provided on the two fins 101-1 and 101-2.

A of FIG. 19 illustrates a configuration example which includes an amplification transistor 23g having a wide contact electrode 38g and a gate electrode 31g so provided as to cross over the fin 101-1 and the fin 101-2 and a selection transistor 24g having a wide contact electrode 41g and a gate electrode 33g so provided as to cross over the fin 101-1 and the fin 101-2. The amplification transistor 23g and the selection transistor 24g configured as above can lower resistance in association with an increase in the contact areas.

B of FIG. 19 illustrates a configuration example which includes an amplification transistor 23h having a wide contact electrode 38h so provided as to cross over the fin 101-1 and the fin 101-2 and having a gate electrode 31h-1 and a gate electrode 31h-2 on the fin 101-1 and the fin 101-2, respectively, and a selection transistor 24h having a wide contact electrode 41h so provided as to cross over the fin 101-1 and the fin 101-2 and having a gate electrode 33h-1 and a gate electrode 33h-2 on the fin 101-1 and the fin 101-2, respectively. The amplification transistor 23h and the selection transistor 24h configured as above can reduce parasitic capacitance by reducing the side areas, and can lower resistance in association with an increase in the contact areas.

C of FIG. 19 illustrates a configuration example which includes an amplification transistor 23i having a wide contact electrode 38i so provided as to cross over the fin 101-1 and the fin 101-2 and having a gate electrode 31i containing the cut 104 and a selection transistor 24i having a wide contact electrode 41i so provided as to cross over the fin 101-1 and the fin 101-2 and having a gate electrode 33i containing the cut 105. The amplification transistor 23i and the selection transistor 24i configured as above can reduce parasitic capacitance by reducing the side areas, and can lower resistance in association with an increase in the contact areas.

D of FIG. 19 illustrates a configuration example which includes an amplification transistor 23j having a wide contact electrode 38j so provided as to cross over the fin 101-1 and the fin 101-2 and having a gate electrode 31j containing the cut 104 and a selection transistor 24j having a wide contact electrode 41j so provided as to cross over the fin 101-1 and the fin 101-2 and having a gate electrode 33j containing the cut 105. The amplification transistor 23j and the selection transistor 24j configured as above can reduce parasitic capacitance by reducing the side areas, and can lower resistance in association with an increase in the contact areas.

While FIG. 19 illustrates the configuration example which includes the two fins 101-1 and 101-2, a configuration which includes two or more fins 101 may be adopted.

While the amplification transistor 23 and the selection transistor 24 connected in series have been described in the present embodiment, the present technology is applicable to transistors having other functions as long as these transistors are two transistors connected in series.

### Pixel Circuit Diagram

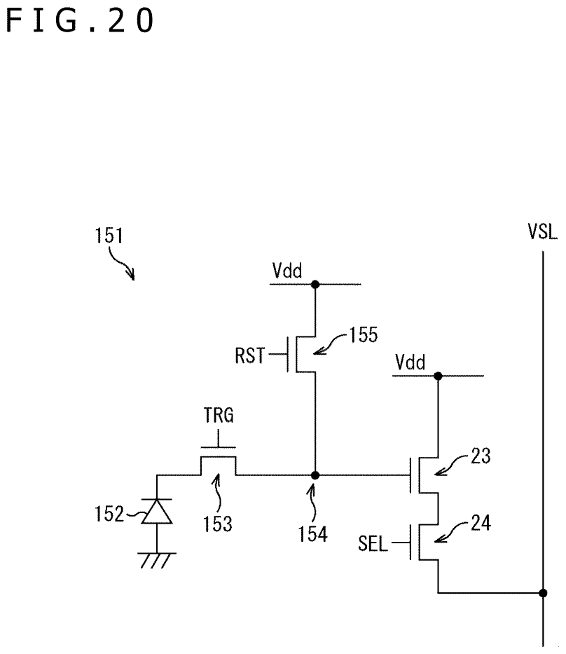

FIG. 20 is a diagram illustrating an example of a circuit diagram of a pixel 151 including the amplification transistor 23 and the selection transistor 24.

As illustrated in FIG. 20, the pixel 151 includes a photodiode 152, a transfer transistor 153, a floating diffusion section 154, and a reset transistor 155 in addition to the amplification transistor 23 and the selection transistor 24.

The photodiode 152 photoelectrically converts light applied to the pixel 151 and generates charge. The transfer transistor 153 is turned on or off according to a transfer signal TRG. When the transfer transistor 153 is turned on, charge generated by the photodiode 152 is transferred to the floating diffusion section 154. The floating diffusion section 154 is connected to a gate electrode of the amplification transistor 23. Charge accumulated in the floating diffusion section 154 is amplified by the amplification transistor 23 and converted into a pixel signal. The selection transistor 24 is turned on or off according to a selection signal SEL. When the selection transistor 24 is turned on, the pixel signal converted by the amplification transistor 23 is output to a vertical signal line VSL. The reset transistor 155 is turned on or off according to a reset signal RST. When the reset transistor 155 is turned on, charge accumulated in the floating diffusion section 154 is discharged to a power source Vdd. As a result, the floating diffusion section 154 is reset.

### Configuration Example of Electronic Equipment

For example, the imaging device 11 described above is applicable to various types of electronic equipment, including an imaging system such as a digital still camera and a digital video camera, a cellular phone having an imaging function, and other types of equipment having an imaging function.

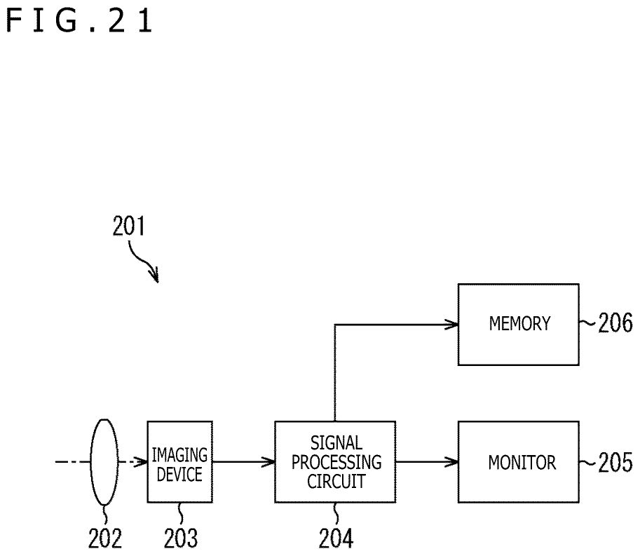

FIG. 21 is a block diagram illustrating a configuration example of an imaging apparatus mounted on electronic equipment.

As illustrated in FIG. 21, an imaging apparatus 201 includes an optical system 202, an imaging device 203, a signal processing circuit 204, a monitor 205, and a memory 206, and is configured to capture still images and moving images.

The optical system 202 including one or a plurality of lenses introduces image light (incident light) coming from a subject toward the imaging device 203, and forms an image of the light on a light receiving surface (sensor unit) of the imaging device 203.

The imaging device 11 described above is applied to the imaging device 203. Electrons are accumulated on the imaging device 203 for a fixed period of time according to the image formed on the light receiving surface by the optical system 202. Thereafter, signals corresponding to the electrons accumulated on the imaging device 203 are supplied to the signal processing circuit 204.

The signal processing circuit 204 performs various types of signal processing for the pixel signals output from the imaging device 203. Images (image data) formed as a result of signal processing performed by the signal processing circuit 204 are supplied to and displayed on the monitor 205, or supplied to and stored (recorded) in the memory 206.

The imaging apparatus 201 configured as above can capture higher quality images, for example, by adopting the imaging device 11 described above.

### Use Examples of Image Sensor

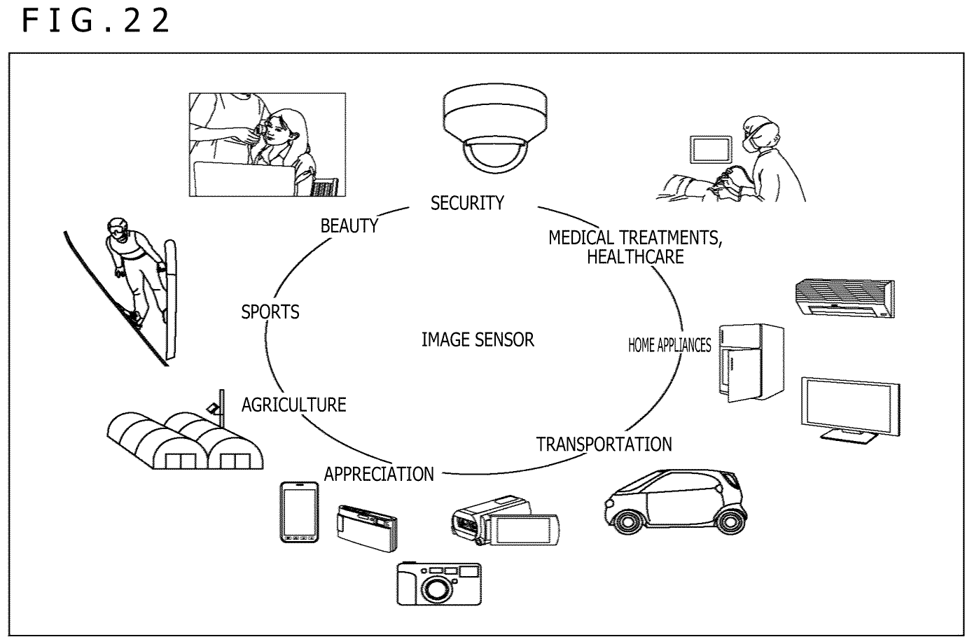

FIG. 22 is a diagram illustrating use examples of the image sensor (imaging device) described above.

As presented below, the image sensor described above is available for various cases for sensing light, such as visible light, infrared light, ultraviolet light, and X-rays, for example.
Devices for capturing images used for appreciation, such as digital cameras and portable devices having a camera function
Devices used for transportation, such as in-vehicle sensors for capturing images of the front, rear, around, and interiors of cars, or other areas associated with cars, monitoring cameras for monitoring traveling vehicles and roads, and distance measuring sensors for measuring distances between vehicles or the like, for purposes of safe driving such as automatic stops, recognition of conditions of drivers, and the like
Devices used for home appliances, such as TV sets, refrigerators, and air conditioners, for purposes of capturing images of gestures of users and performing device operations corresponding to these gestures
Devices used for medical treatments and healthcare, such as endoscopes and devices performing angiogram with received infrared light
Devices used for security, such as monitoring cameras for crime prevention and cameras for person recognition
Devices used for beauty, such as skin measuring devices for capturing images of skin and microscopes for capturing images of scalp
Devices used for sports, such as action cameras and wearable cameras for sports
Devices used for agriculture, such as cameras for monitoring conditions of fields and crops

### Examples of Application to Moving Body

The technology according to the present disclosure (present technology) is applicable to various products. For example, the technology according to the present disclosure may be implemented as a device mounted on a moving body selected from any one of types such as cars, electric cars, hybrid electric cars, motorcycles, bicycles, personal mobilities, airplanes, drones, vessels, and robots.

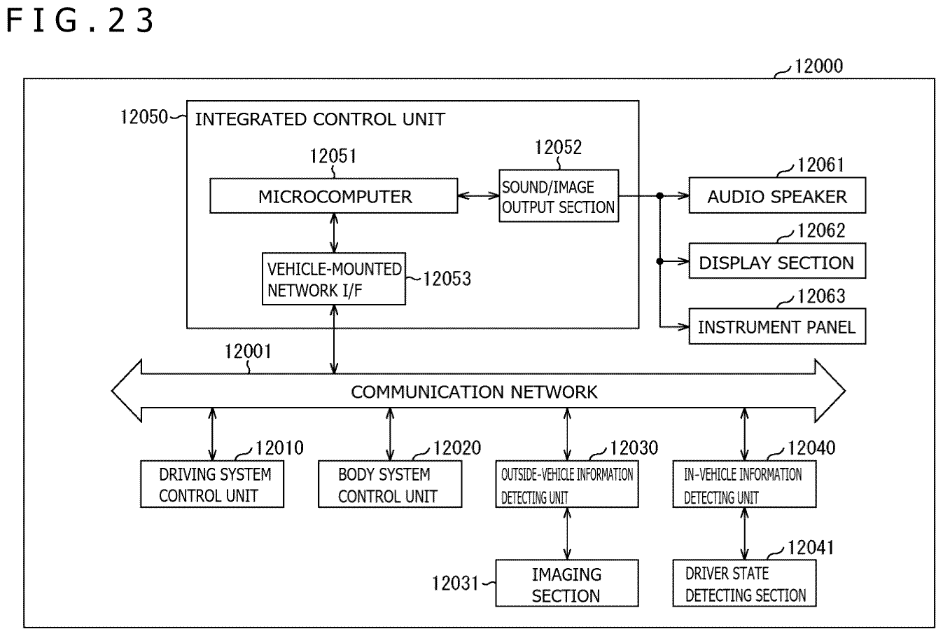

FIG. 23 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

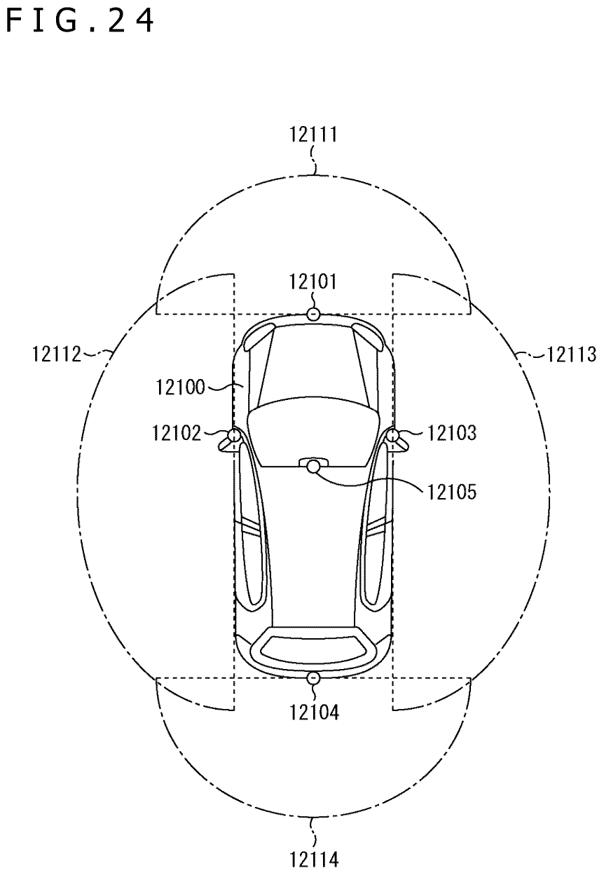

FIG. 24 is a diagram depicting an example of the installation position of the imaging section 12031.

In FIG. 24, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 24 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure is applicable has been described above. For example, the technology according to the present disclosure is applicable to the imaging section 12031 and the like in the configurations described above. For example, the technology according to the present disclosure applied to the imaging section 12031 and the like can improve reliability by raising performance.

### Application Examples

The technology according to the present disclosure is applicable to medical imaging systems. Medical imaging systems are medical systems using imaging technologies, such as endoscopic systems and microscopic systems.

### Endoscope System

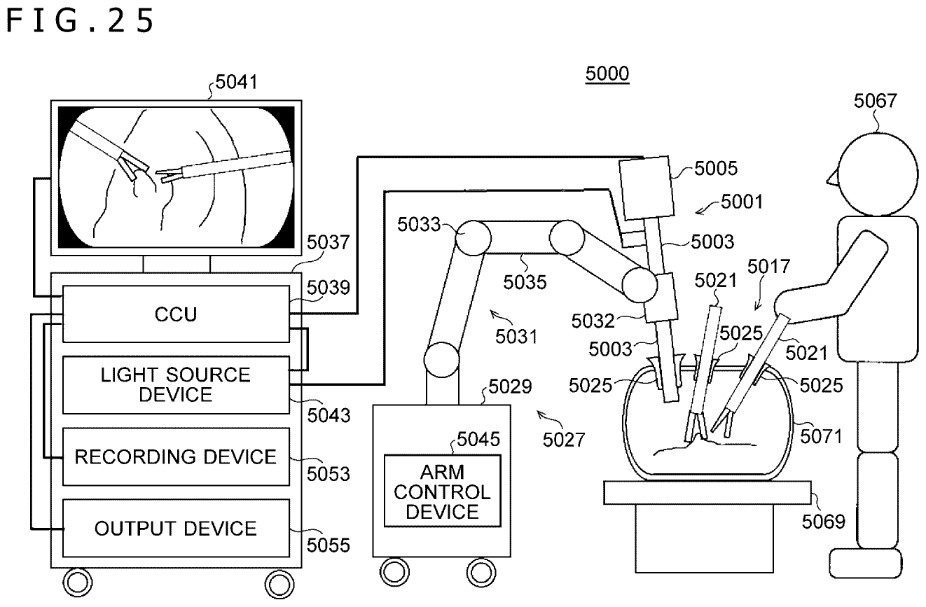

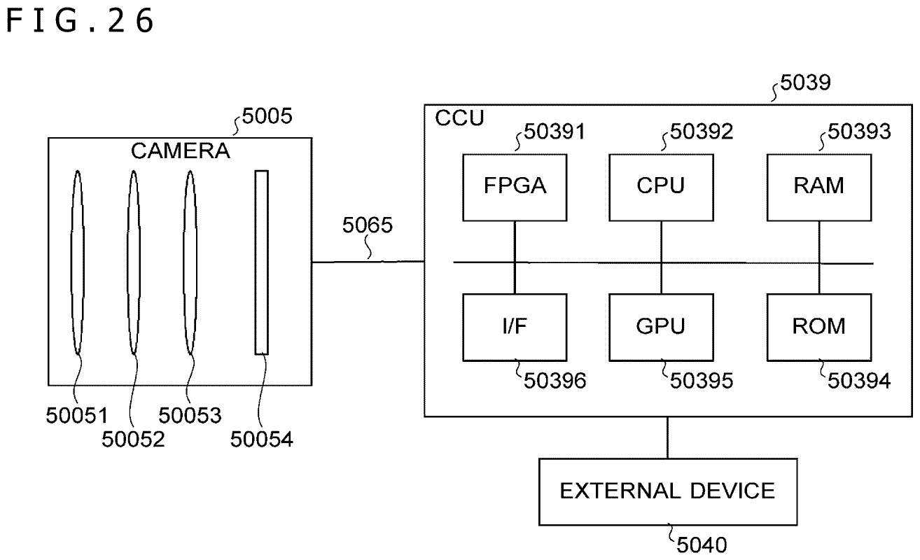

An example of the endoscope system will be described using FIGS. 25 and 26. FIG. 25 is a diagram illustrating an example of a schematic configuration of an endoscope system 5000 to which the technology according to the present disclosure is applicable. FIG. 26 is a diagram illustrating an example of a configuration of an endoscope 5001 and a camera control unit (CCU) 5039. FIG. 25 illustrates a situation where an operator (for example, a doctor) 5067 who is a participant of an operation performs the operation on a patient 5071 on a patient bed 5069 using the endoscope system 5000. As illustrated in FIG. 25, the endoscope system 5000 includes the endoscope 5001 that is a medical imaging device, the CCU 5039, a light source device 5043, a recording device 5053, an output device 5055, and a support device 5027 for supporting the endoscope 5001.

In endoscopic surgery, insertion assisting tools called trocars 5025 are punctured into the patient 5071. Then, a scope 5003 connected to the endoscope 5001 and surgical tools 5021 are inserted into a body of the patient 5071 through the trocars 5025. The surgical tools 5021 include: an energy device such as an electric scalpel; and forceps, for example.

A surgical image that is a medical image in which the inside of the body of the patient 5071 is captured by the endoscope 5001 is displayed on a display device 5041. The operator 5067 performs a procedure on a surgical target using the surgical tools 5021 while viewing the surgical image displayed on the display device 5041. The medical image is not limited to the surgical image, and may be a diagnostic image captured during diagnosis.

### Endoscope

The endoscope 5001 is an imaging section for capturing the inside of the body of the patient 5071, and is, for example, as illustrated in FIG. 26, a camera including a condensing optical system 50051 for condensing incident light, a zooming optical system 50052 capable of optical zooming by changing a focal length of the imaging section, a focusing optical system 50053 capable of focus adjustment by changing the focal length of the imaging section, and a light receiving sensor 50054. The endoscope 5001 condenses the light through the connected scope 5003 on the light receiving sensor 50054 to generate a pixel signal, and outputs the pixel signal through a transmission system to the CCU 5039. The scope 5003 is an insertion part that includes an objective lens at a distal end and guides the light from the connected light source device 5043 into the body of the patient 5071. The scope 5003 is, for example, a rigid scope for a rigid endoscope and a flexible scope for a flexible endoscope. The scope 5003 may be a direct viewing scope or an oblique viewing scope. The pixel signal only needs to be a signal based on a signal output from a pixel, and is, for example, a raw signal or an image signal. The transmission system connecting the endoscope 5001 to the CCU 5039 may include a memory, and the memory may store parameters related to the endoscope 5001 and the CCU 5039. The memory may be disposed at a connection portion of the transmission system or on a cable. For example, the memory of the transmission system may store the parameters before shipment of the endoscope 5001 or the parameters changed when current is applied, and an operation of the endoscope may be changed based on the parameters read from the memory. A set of the camera and the transmission system may be referred to as an endoscope. The light receiving sensor 50054 is a sensor for converting the received light into the pixel signal, and is, for example, a complementary metal-oxide-semiconductor (CMOS) imaging sensor. The light receiving sensor 50054 is preferably an imaging sensor having a Bayer array capable of color imaging. The light receiving sensor 50054 is also preferably an imaging sensor having a number of pixels corresponding to a resolution of, for example, 4K (3840 horizontal pixels×2160 vertical pixels), 8K (7680 horizontal pixels×4320 vertical pixels), or square 4K (3840 or more horizontal pixels×3840 or more vertical pixels). The light receiving sensor 50054 may be one sensor chip, or a plurality of sensor chips. For example, a prism may be provided to separate the incident light into predetermined wavelength bands, and the wavelength bands may be imaged by different light receiving sensors. A plurality of light receiving sensors may be provided for stereoscopic viewing. The light receiving sensor 50054 may be a sensor having a chip structure including an arithmetic processing circuit for image processing, or may be a sensor for time of flight (ToF). The transmission system is, for example, an optical fiber cable system or a wireless transmission system. The wireless transmission only needs to be capable of transmitting the pixel signal generated by the endoscope 5001, and, for example, the endoscope 5001 may be wirelessly connected to the CCU 5039, or the endoscope 5001 may be connected to the CCU 5039 via a base station in an operating room. At this time, the endoscope 5001 may transmit not only the pixel signal, but also simultaneously information (for example, a processing priority of the pixel signal and/or a synchronization signal) related to the pixel signal. In the endoscope, the scope may be integrated with the camera, and the light receiving sensor may be provided at the distal end of the scope.

### Camera Control Unit (CCU)

The CCU 5039 is a control device for controlling the endoscope 5001 and the light source device 5043 connected to the CCU 5039 in an integrated manner, and is, for example, as illustrated in FIG. 26, an image processing device including a field-programmable gate array (FPGA) 50391, a central processing unit (CPU) 50392, a random access memory 50393, a read-only memory (ROM) 50394, a graphics processing unit (GPU) 50395, and an interface (I/F) 50396. The CCU 5039 may control the display device 5041, the recording device 5053, and the output device 5055 connected to the CCU 5039 in an integrated manner. The CCU 5039 controls, for example, irradiation timing, irradiation intensity, and a type of an irradiation light source of the light source device 5043. The CCU 5039 also performs image processing, such as development processing (for example, demosaic processing) and correction processing, on the pixel signal output from the endoscope 5001, and outputs the processed image signal (for example, an image) to an external device such as the display device 5041. The CCU 5039 also transmits a control signal to the endoscope 5001 to control driving of the endoscope 5001. The control signal is information on an imaging condition such as a magnification or the focal length of the imaging section. The CCU 5039 may have a function to down-convert the image, and may be configured to be capable of simultaneously outputting a higher-resolution (for example, 4K) image to the display device 5041 and a lower-resolution (for example, high-definition (HD)) image to the recording device 5053.

The CCU 5039 may be connected to external equipment (such as a recording device, a display device, an output device, and a support device) via an IP converter for converting the signal into a predetermined communication protocol (such as the Internet Protocol (IP)). The connection between the IP converter and the external equipment may be established using a wired network, or a part or the whole of the network may be established using a wireless network. For example, the IP converter on the CCU 5039 side may have a wireless communication function, and may transmit the received image to an IP switcher or an output side IP converter via a wireless communication network, such as the fifth-generation mobile communication system (5G) or the sixth-generation mobile communication system (6G).

### Light Source Device

The light source device 5043 is a device capable of emitting the light having predetermined wavelength bands, and includes, for example, a plurality of light sources and a light source optical system for guiding the light of the light sources. The light sources are, for example, xenon lamps, light-emitting diode (LED) light sources, or laser diode (LD) light sources. The light source device 5043 includes, for example, the LED light sources corresponding to three respective primary colors of red (R), green (G), and blue (B), and controls output intensity and output timing of each of the light sources to emit white light. The light source device 5043 may include a light source capable of emitting special light used for special light observation, in addition to the light sources for emitting normal light for normal light observation. The special light is light having a predetermined wavelength band different from that of the normal light being light for the normal light observation, and is, for example, near-infrared light (light having a wavelength of 760 nm or longer), infrared light, blue light, or ultraviolet light. The normal light is, for example, the white light or green light. In narrow band imaging that is a kind of special light observation, blue light and green light are alternately emitted, and thus the narrow band imaging can image a predetermined tissue such as a blood vessel in a mucosal surface at high contrast using wavelength dependence of light absorption in the tissue of the body. In fluorescence observation that is a kind of special light observation, excitation light is emitted for exciting an agent injected into the tissue of the body, and fluorescence emitted by the tissue of the body or the agent as a label is received to obtain a fluorescent image, and thus the fluorescence observation can facilitate the operator to view, for example, the tissue of the body that is difficult to be viewed by the operator with the normal light. For example, in fluorescence observation using the infrared light, the infrared light having an excitation wavelength band is emitted to an agent, such as indocyanine green (ICG), injected into the tissue of the body, and the fluorescence light from the agent is received, whereby the fluorescence observation can facilitate viewing of a structure and an affected part of the tissue of the body. In the fluorescence observation, an agent (such as 5-aminolevulinic acid (5-ALA)) may be used that emits fluorescence in a red wavelength band by being excited by the special light in a blue wavelength band. The type of the irradiation light of the light source device 5043 is set by control of the CCU 5039. The CCU 5039 may have a mode of controlling the light source device 5043 and the endoscope 5001 to alternately perform the normal light observation and the special light observation. At this time, information based on a pixel signal obtained by the special light observation is preferably superimposed on a pixel signal obtained by the normal light observation. The special light observation may be an infrared light observation to observe a site inside the surface of an organ and a multi-spectrum observation utilizing hyperspectral spectroscopy. A photodynamic therapy may be incorporated.

### Recording Device

The recording device 5053 is a device for recording the pixel signal (for example, an image) acquired from the CCU 5039, and is, for example, a recorder. The recording device 5053 records an image acquired from the CCU 5039 in a hard disk drive (HDD), a Super Density Disc (SDD), and/or an optical disc. The recording device 5053 may be connected to a network in a hospital to be accessible from equipment outside the operating room. The recording device 5053 may have a down-convert function or an up-convert function.

### Display Device

The display device 5041 is a device capable of displaying the image, and is, for example, a display monitor. The display device 5041 displays a display image based on the pixel signal acquired from the CCU 5039. The display device 5041 may include a camera and a microphone to function as an input device that allows instruction input through gaze recognition, voice recognition, and gesture.

### Output Device

The output device 5055 is a device for outputting the information acquired from the CCU 5039, and is, for example, a printer. The output device 5055 prints, for example, a print image based on the pixel signal acquired from the CCU 5039 on a sheet of paper.

### Support Device

The support device 5027 is an articulated arm including a base 5029 including an arm control device 5045, an arm 5031 extending from the base 5029, and a holding part 5032 mounted at a distal end of the arm 5031. The arm control device 5045 includes a processor such as a CPU, and operates according to a predetermined computer program to control driving of the arm 5031. The support device 5027 uses the arm control device 5045 to control parameters including, for example, lengths of links 5035 constituting the arm 5031 and rotation angles and torque of joints 5033 so as to control, for example, the position and attitude of the endoscope 5001 held by the holding part 5032. This control can change the position or attitude of the endoscope 5001 to a desired position or attitude, makes it possible to insert the scope 5003 into the patient 5071, and can change the observed area in the body. The support device 5027 functions as an endoscope support arm for supporting the endoscope 5001 during the operation. Thus, the support device 5027 can play a role of a scopist who is an assistant holding the endoscope 5001. The support device 5027 may be a device for holding a microscope device 5301 to be described later, and can be called a medical support arm. The support device 5027 may be controlled using an autonomous control method by the arm control device 5045, or may be controlled using a control method in which the arm control device 5045 performs the control based on input of a user. The control method may be, for example, a master-slave method in which the support device 5027 serving as a slave device (replica device) that is a patient cart is controlled based on a movement of a master device (primary device) that is an operator console at a hand of the user. The support device 5027 may be remotely controllable from outside the operating room.

The example of the endoscope system 5000 to which the technology according to the present disclosure is applicable has been described above. For example, the technology according to the present disclosure may be applied to a microscope system.

### Microscope System

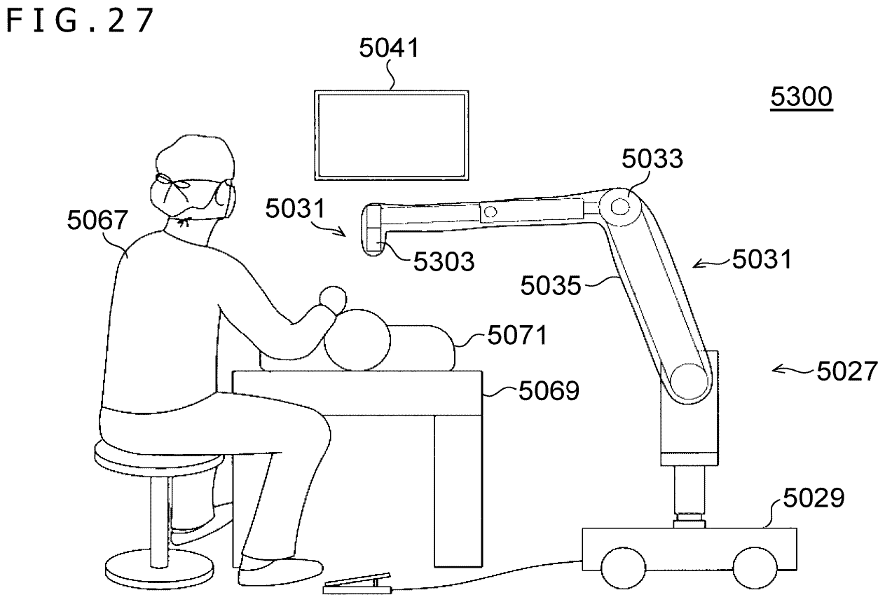

FIG. 27 is a diagram illustrating an example of a schematic configuration of a microscopic surgery system to which the technology according to the present disclosure is applicable. In the following description, the same components as those of the endoscope system 5000 will be denoted by the same reference numerals, and the description thereof will not be repeated.

FIG. 27 schematically illustrates a situation where the operator 5067 performs an operation on the patient 5071 on the patient bed 5069 using a microscopic surgery system 5300. For the sake of simplicity, FIG. 27 does not illustrate a cart 5037 among the components of the microscopic surgery system 5300, and illustrates the microscope device 5301 instead of the endoscope 5001 in a simplified manner. The microscope device 5301 may refer to a microscope 5303 provided at the distal end of the links 5035, or may refer to the overall configuration including the microscope 5303 and the support device 5027.

As illustrated in FIG. 27, during the operation, the microscopic surgery system 5300 is used to display an image of a surgical site captured by the microscope device 5301 in a magnified manner on the display device 5041 installed in the operating room. The display device 5041 is installed in a position facing the operator 5067, and the operator 5067 performs various procedures, such as excision of an affected part, on the surgical site while observing the state of the surgical site using the image displayed on the display device 5041. The microscopic surgery system is used in, for example, ophthalmic operation and neurosurgical operation.

The respective examples of the endoscope system 5000 and the microscopic surgery system 5300 to which the technology according to the present disclosure is applicable have been described above. Systems to which the technology according to the present disclosure is applicable are not limited to such examples. For example, the support device 5027 can support, at the distal end thereof, another observation device or another surgical tool instead of the endoscope 5001 or the microscope 5303. Examples of the other applicable observation device include forceps, tweezers, a pneumoperitoneum tube for pneumoperitoneum, and an energy treatment tool for incising a tissue or sealing a blood vessel by cauterization. By using the support device to support the observation device or the surgical tool described above, the position thereof can be more stably fixed and the load of the medical staff can be lower than in a case where the medical staff manually supports the observation device or the surgical tool. The technology according to the present disclosure may be applied to a support device for supporting such a component other than the microscope.

The technology according to the present disclosure is applicable to the endoscope 5001 and the like in the configurations described above as an appropriate use example. For example, the technology according to the present disclosure applied to the endoscope 5001 and the like can improve reliability by raising performance.

### Combination Examples of Configurations

Note that the present technology can also take the following configurations.
(1)

A solid-state imaging device including:
a first transistor that includes a sidewall surrounding a side surface of the first transistor;
a second transistor that is connected in series with the first transistor and includes a sidewall surrounding a side surface of the second transistor;
a first high-concentration diffusion layer that is provided on a semiconductor substrate and reaches a lower side of the sidewall on a drain side of the first transistor; and
a third high-concentration diffusion layer that is provided on the semiconductor substrate between the first transistor and the second transistor and reaches a lower side of the sidewall on a source side of the first transistor, in which
the first high-concentration diffusion layer has a lower impurity concentration than the third high-concentration diffusion layer.
(2)

The solid-state imaging device according to (1) above, further including:
a second high-concentration diffusion layer provided on the drain side of the first transistor, and used as a contact forming region for connection with a contact electrode that supplies a drain power source to the first transistor, in which
the second high-concentration diffusion layer has a higher impurity concentration than the first high-concentration diffusion layer, and
the first high-concentration diffusion layer has a predetermined width or larger.
(3)

The solid-state imaging device according to (1) or (2) above, further including:
a low-concentration diffusion layer provided at an end of a gate electrode of the first transistor and an end of the second transistor.
(4)

The solid-state imaging device according to any one of (1) through (3) above, further including:
a first film that covers a gate electrode and the sidewall of the first transistor and a gate electrode and the sidewall of the second transistor; and
a second film laminated on the first film, in which
the second film has an opening that opens between the first transistor and the second transistor.
(5)

The solid-state imaging device according to (4) above, in which a distance between end surfaces of the opening formed in the second film is larger than a distance between the gate electrode of the first transistor and the gate electrode of the second transistor.
(6)

The solid-state imaging device according to (4) or (5) above, in which the third high-concentration diffusion layer is formed by ion implantation that uses, as a mask, the second film having the opening.
(7)

The solid-state imaging device according to (6) above, in which the third high-concentration diffusion layer and the second high-concentration diffusion layer are formed by different steps.
(8)

The solid-state imaging device according to any one of (4) through (7) above, in which the second film is formed at least between the opening and a side surface of the sidewall on the drain side of the first transistor.
(9)

The solid-state imaging device according to any one of (4) through (8) above, in which the second film is provided such that a distance between a reference set to a side surface of the first film covering the gate electrode of the first transistor and a side surface of a contact electrode connected to the gate electrode of the first transistor is larger than or equal to a distance between the reference and an end surface of the opening.
(10)

The solid-state imaging device according to any one of (4) through (9) above, in which
the first film is an oxide film, and
the second film is a nitride film.
(11)

The solid-state imaging device according to any one of (1) through (10) above, in which a contact electrode that supplies a drain power source to the first transistor is connected to the first high-concentration diffusion layer.
(12)

The solid-state imaging device according to any one of (1) through (11) above, further including:
a pseudo contact electrode that is provided between a gate electrode of the first transistor and a gate electrode of the second transistor, and has one end connected to the semiconductor substrate and another end not connected.
(13)

The solid-state imaging device according to (12) above, in which the third high-concentration diffusion layer is formed by ion implantation using a through hole formed in an interlayer film at a time of formation of the pseudo contact electrode.
(14)

The solid-state imaging device according to any one of (1) through (13) above, in which the first transistor and the second transistor are linearly arranged in a planar view, or cross each other substantially at right angles in a planar view.
(15)

The solid-state imaging device according to any one of (1) through (14) above, in which each of the first transistor and the second transistor has a fin structure that has a fin protruded with respect to the semiconductor substrate and extending from the drain side of the first transistor to the source side of the second transistor.
(16)

The solid-state imaging device according to (15) above, in which each of the first transistor and the second transistor has a plurality of the fins.
(17)

The solid-state imaging device according to (15) or (16) above, in which each of a contact electrode connected to the drain side of the first transistor and a contact electrode connected to the source side of the second transistor has a wide shape in contact with an upper surface and a side surface of the fin.
(18)

The solid-state imaging device according to any one of (1) through (11) above, in which
the first transistor is an amplification transistor, and
the second transistor is a selection transistor.
(19)

A manufacturing method of a solid-state imaging device including a first transistor that includes a sidewall surrounding a surface of the first transistor and a second transistor that is connected in series with the first transistor and includes a sidewall surrounding a side surface of the second transistor, the manufacturing method including:
forming a first high-concentration diffusion layer that is provided on a semiconductor substrate and reaches a lower side of the sidewall on a drain side of the first transistor; and
forming a third high-concentration diffusion layer that is provided on the semiconductor substrate between the first transistor and the second transistor and reaches a lower side of the sidewall on a source side of the first transistor, in which
the first high-concentration diffusion layer has a lower impurity concentration than the third high-concentration diffusion layer.
(20)

Electronic equipment including:
a solid-state imaging device,
the solid-state imaging device including
   a first transistor that includes a sidewall surrounding a side surface of the first transistor,
   a second transistor that is connected in series with the first transistor and includes a sidewall surrounding a side surface of the second transistor,
   a first high-concentration diffusion layer that is provided on a semiconductor substrate and reaches a lower side of the sidewall on a drain side of the first transistor, and
   a third high-concentration diffusion layer that is provided on the semiconductor substrate between the first transistor and the second transistor and reaches lower side of the side wall on a source side of the first transistor, and
the first high-concentration diffusion layer having a lower impurity concentration than the third high-concentration diffusion layer.

Note that the present embodiments are not limited to the embodiments described above, and can be modified in various manners without departing from the scope of the subject matters of the present disclosure. Moreover, advantageous effects to be offered are not limited to the advantageous effects described in the present description only by way of example. Other advantageous effects may additionally be offered.

### REFERENCE SIGNS LIST

11: Imaging device
21: Semiconductor substrate
22: Wiring layer
23: Amplification transistor
24: Selection transistor
25 and 26: Gate insulation film
31: Gate electrode
32: Sidewall
33: Gate electrode
34: Sidewall
35: Oxide film
36: Nitride film
37: Interlayer film
38 through 41: Contact electrode
42 through 45: Wire
51: P-type well layer
52: Low-concentration diffusion layer
53: First high-concentration diffusion layer
54: Second high-concentration diffusion layer
55: Third high-concentration diffusion layer
61: Opening
62 and 63: End surface
81: Pseudo contact electrode
101: Fin
102 and 103: Slit
104 and 105: Cut

1. A solid-state imaging device comprising:
a first transistor that includes a sidewall surrounding a side surface of the first transistor;
a second transistor that is connected in series with the first transistor and includes a sidewall surrounding a side surface of the second transistor;
a first high-concentration diffusion layer that is provided on a semiconductor substrate and reaches a lower side of the sidewall on a drain side of the first transistor; and
a third high-concentration diffusion layer that is provided on the semiconductor substrate between the first transistor and the second transistor and reaches a lower side of the sidewall on a source side of the first transistor, wherein
the first high-concentration diffusion layer has a lower impurity concentration than the third high-concentration diffusion layer.

2. The solid-state imaging device according to claim 1, further comprising:
a second high-concentration diffusion layer provided on the drain side of the first transistor, and used as a contact forming region for connection with a contact electrode that supplies a drain power source to the first transistor, wherein
the second high-concentration diffusion layer has a higher impurity concentration than the first high-concentration diffusion layer, and
the first high-concentration diffusion layer has a predetermined width or larger.

3. The solid-state imaging device according to claim 1, further comprising:
a low-concentration diffusion layer provided at an end of a gate electrode of the first transistor and an end of the second transistor.

4. The solid-state imaging device according to claim 2, further comprising:
a first film that covers a gate electrode and the sidewall of the first transistor and a gate electrode and the sidewall of the second transistor; and
a second film laminated on the first film, wherein
the second film has an opening that opens between the first transistor and the second transistor.

5. The solid-state imaging device according to claim 4, wherein a distance between end surfaces of the opening formed in the second film is larger than a distance between the gate electrode of the first transistor and the gate electrode of the second transistor.

6. The solid-state imaging device according to claim 5, wherein the third high-concentration diffusion layer is formed by ion implantation that uses, as a mask, the second film having the opening.

7. The solid-state imaging device according to claim 6, wherein the third high-concentration diffusion layer and the second high-concentration diffusion layer are formed by different steps.

8. The solid-state imaging device according to claim 4, wherein the second film is formed at least between the opening and a side surface of the sidewall on the drain side of the first transistor.

9. The solid-state imaging device according to claim 4, wherein the second film is provided such that a distance between a reference set to a side surface of the first film covering the gate electrode of the first transistor and a side surface of a contact electrode connected to the gate electrode of the first transistor is larger than or equal to a distance between the reference and an end surface of the opening.

10. The solid-state imaging device according to claim 4, wherein
the first film is an oxide film, and
the second film is a nitride film.

11. The solid-state imaging device according to claim 1, wherein a contact electrode that supplies a drain power source to the first transistor is connected to the first high-concentration diffusion layer.

12. The solid-state imaging device according to claim 1, further comprising:
a pseudo contact electrode that is provided between a gate electrode of the first transistor and a gate electrode of the second transistor, and has one end connected to the semiconductor substrate and another end not connected.

13. The solid-state imaging device according to claim 12, wherein the third high-concentration diffusion layer is formed by ion implantation using a through hole formed in an interlayer film at a time of formation of the pseudo contact electrode.

14. The solid-state imaging device according to claim 1, wherein the first transistor and the second transistor are linearly arranged in a planar view, or cross each other substantially at right angles in a planar view.

15. The solid-state imaging device according to claim 1, wherein each of the first transistor and the second transistor has a fin structure that has a fin protruded with respect to the semiconductor substrate and extending from the drain side of the first transistor to the source side of the second transistor.

16. The solid-state imaging device according to claim 15, wherein each of the first transistor and the second transistor has a plurality of the fins.

17. The solid-state imaging device according to claim 16, wherein each of a contact electrode connected to the drain side of the first transistor and a contact electrode connected to the source side of the second transistor has a wide shape in contact with an upper surface and a side surface of the fin.

18. The solid-state imaging device according to claim 1, wherein
the first transistor is an amplification transistor, and
the second transistor is a selection transistor.

19. A manufacturing method of a solid-state imaging device including a first transistor that includes a sidewall surrounding a surface of the first transistor and a second transistor that is connected in series with the first transistor and includes a sidewall surrounding a side surface of the second transistor, the manufacturing method comprising:
forming a first high-concentration diffusion layer that is provided on a semiconductor substrate and reaches a lower side of the sidewall on a drain side of the first transistor; and
forming a third high-concentration diffusion layer that is provided on the semiconductor substrate between the first transistor and the second transistor and reaches a lower side of the sidewall on a source side of the first transistor, wherein
the first high-concentration diffusion layer has a lower impurity concentration than the third high-concentration diffusion layer.

20. Electronic equipment comprising:
a solid-state imaging device,
the solid-state imaging device including
a first transistor that includes a sidewall surrounding a side surface of the first transistor,
a second transistor that is connected in series with the first transistor and includes a sidewall surrounding a side surface of the second transistor,
a first high-concentration diffusion layer that is provided on a semiconductor substrate and reaches a lower side of the sidewall on a drain side of the first transistor, and
a third high-concentration diffusion layer that is provided on the semiconductor substrate between the first transistor and the second transistor and reaches lower side of the side wall on a source side of the first transistor, and
the first high-concentration diffusion layer having a lower impurity concentration than the third high-concentration diffusion layer.
